(19) United States
(12) Patent Application Publication
(10) Pub. No.: US 2014/0332077 A1
(43) Pub. Date: Nov. 13, 2014

(54) SUB-WAVELENGTH STRUCTURES, DEVICES AND METHODS FOR LIGHT CONTROL IN MATERIAL COMPOSITES

(71) Applicant: RESEARCH FOUNDATION OF THE CITY UNIVERSITY OF NEW YORK, New York, NY (US)

(72) Inventors: David Thomas Crouse, New York, NY (US); Pavan Kumar Reddy Keshavareddy, Jersey City, NJ (US)

(73) Assignee: RESEARCH FOUNDATION OF THE CITY UNIVERSITY OF NEW YORK, New York, NY (US)

(21) Appl. No.: 14/446,766

(22) Filed: Jul. 30, 2014

Related U.S. Application Data
(63) Continuation of application No. 12/746,897, filed on Sep. 20, 2010, now abandoned.
Application No. 12/746,897 is a continuation-in-part of application No. PCT/US2007/025351, filed on Oct. 12, 2007.

(51) Int. Cl. G02B 5/30; H01L 31/052; G01J 4/00

(52) U.S. Cl. CPC G02B 5/3058; G01J 4/00; H01L 31/0522; G01J 2004/001
USPC 136/259; 356/365; 359/484.01

(57) ABSTRACT

A device for enhancing transmission of incident electromagnetic radiation at a predetermined wavelength is presented that includes an aperture array structure in a thin film. The structure includes a repealing unit cell having more than one aperture including a first aperture and a second aperture, wherein a parameter of the first aperture differs from that of the second aperture. The unit cell repeats with a periodicity on the order of or less than said predetermined wavelength, The structure parameters are configured to preferentially support cavity modes for coupling to and enhancing transmission of a predetermined polarization state at the predetermined wavelength. By structuring the unit cell with apertures that differ by appropriate degrees in at least one of dimension, height, dielectric constant of material filling the apertures, shape, and orientation, the devices can be adapted for polarization and/or wavelength filtering- and/or light circulating, weaving, or channeling.

### CROSS-REFERENCE TO RELATED APPLICATIONS

This application claims priority to international patent application PCT/US07/25351 filed Dec. 10, 2007, which claims priority to U.S. provisional application Ser. No. 60/874,037, filed Dec. 8, 2006, and also claims priority to pending U.S. patent application Ser. No. 61/191,292, entitled “Horizontally Distributed, Tandem Solar Cells Using Surface Plasmons and Resonant Cavity Mode,” filed Sep. 8, 2008, the entireties of which are incorporated herein by reference.

### GOVERNMENT RIGHTS

The U.S. Government may have certain rights in this invention including the right in limited circumstances to require the patent owner to license others on reasonable terms as provided for by the terms of a Phase I Small Business Innovative Research (SBIR) Contract No. 0539541, entitled “Advanced Silicon-based Photodetectors Using Light Localization and Channeling” awarded by the National Science Foundation.

### FIELD OF THE INVENTION

This invention relates generally to sub-wavelength periodic structures for enhanced transmission of incident optical radiation and, more particularly, to sub-wavelength aperture array structures and grating structures with polarization tunability and enhanced transmission, having geometries adapted to support coupled mode resonances for enhanced transmission, fight channeling, circulating, and weaving. This invention further relates to devices that include such structures.

### BACKGROUND OF THE INVENTION

There has been much interest in the phenomenon of enhanced transmission in periodically patterned metal structures, both in two-dimensionally periodic hole-arrays and in one-dimensionally periodic transmission grating structures. Referring to FIG. 1, enhanced transmission is a known phenomenon that can occur in certain conditions when light is incident on a periodically patterned optically-thick grating structure 10 having metal contacts 12. A typical Poynting vector 20 of the electromagnetic field incident 16 on the grating structure 10 is shown in FIG. 1 for illustration.

Enhanced transmission occurs when incident light 16 is transmitted with a transmittance (7) greater than a ratio of the area (A_{groove}) of grooves 14 that separate the contacts 12 to the total area of the structure 10 on which incident light 16 impinges (Aₜₒₜₐₗ), as described by Equation 1 below:

T>A_{groove}/Aₜₒₜₐₗ. (I)

Hence, the incident light 16 is channeled around the metal contacts 12 and through the grooves 14 of the grating structure 10 to transmit radiation 18. Structures with grooves having an area of only a few percent of the total area of the film have been found to transmit close to 100% of the incident light at particular wavelengths, polarization states and angles of incidence.

Enhanced optical transmission is an extremely useful property that can be exploited for use in a variety of optical devices, if it can be accurately modeled for different applications. Until fairly recently, this phenomenon was attributed to horizontally oriented surface plasmons (HSPs), surface plasmons that are oriented parallel to the surface, for both one-dimensional periodic grating structures and two dimensionally periodic hole arrays. Accordingly, these prior art enhanced transmission gratings have been limited to specific configurations designed to optimize HSP coupling.

For example, U.S. Pat. No. 5,973,316 to Ebbesen et al. (“Ebbesen”) discloses an array of low profile sub-wavelength apertures in a thin metallic film or thin metal plate for enhanced light transmission by coupling to an HSP mode, where the period of the array is chosen to enhance transmission within a particular wavelength range. Ebbesen further discloses that the array can be used to filter and collect light for photolithographic applications.

In another example, U.S. Pat. No. 5,625,729 to Brown discloses an optoelectronic device for resonantly coupling incident radiation to a local surface plasmon wave. The device, e.g., a metal-semiconductor-metal (“MSM”) detector, includes a multiplicity of substantially planar and regularly spaced low-profile electrodes on a semiconductor substrate to resonantly couple an HSP mode propagating along the grating and the substrate.

Those of ordinary skill in the art will appreciate that only incident transverse-magnetic (TM) radiation (defined as electromagnetic radiation with the magnetic field oriented parallel to the grating elements (wires, e.g.)) will couple to HSPs. Accordingly, these and other prior art sub-wavelength enhanced transmission gratings are limited to specific configurations designed to optimize HSP coupling and, consequently, to gratings which enhance transmission of TM radiation.

### SUMMARY OF THE INVENTION

The present invention relates to polarization-tunable enhanced transmission sub-wavelength grating and aperture array structures that can be tuned to selectively transmit a predetermined polarization state or to simultaneously enhance transmission of both TM and transverse-electric (TE) radiation. The present invention also relates to enhanced transmission sub-wavelength structures that support cavity modes (“CMs”), including hybrid cavity modes to produce light-circulating or light-weaving structures, depending on the angle of incident radiation. The sub-wavelength structures of the present invention are easy to fabricate and, consequently, are easy to integrate into devices requiring polarization-tunable transmission. Accordingly, the present invention further relates to devices that include any of the sub-wavelength structures of the present invention.

A device for enhancing transmission of incident electromagnetic radiation at a predetermined wavelength includes a structure comprising an array of apertures in a thin film. The structure is adapted to preferentially support cavity modes for coupling to and enhancing transmission of a predetermined polarization state at the predetermined wavelength. The structure is adapted to induce light circulation or weaving of the transmitted predetermined polarization state at the predetermined wavelength. The array of apertures is arranged with a periodicity that is on the order of or less than the predetermined wavelength.

A device for enhancing transmission of incident electromagnetic radiation at a predetermined wavelength includes a structure comprising an array of apertures in a thin film. The structure includes a repeating unit cell having at least a first aperture and a second aperture, wherein a parameter of the first aperture differs from that of the second aperture. The unit cell repeats with a periodicity on the order of or less than the predetermined wavelength. The structure is adapted to preferentially support cavity modes for coupling to and enhancing transmission of a predetermined polarization state at the predetermined wavelength.

These structures can be stacked with spacer layers of air between them, or with spacer layers comprised of any material which will enhance light circulating, channeling, weaving, or any other enhanced transmission effect described herein.

A device for enhancing transmission of incident electromagnetic radiation within more than one predetermined wavelength band includes a structure comprising an array of apertures in a thin film. The structure includes a repeating unit cell having more than one aperture including a first aperture and a second aperture. A parameter of the first aperture differs from that of the second aperture. The unit cell repeats with a periodicity on the order of or less than the more than one predetermined wavelength. The structure is adapted to preferentially support cavity modes for coupling to and enhancing transmission of unpolarized light within the predetermined wavelength bands. The structure is further adapted to channel light within a first predetermined wavelength band into the first aperture of each unit cell and to channel light within a second predetermined wavelength band into the second aperture of each unit cell.

Such device includes a solar cell, wherein a first aperture is filled with a semiconductor material that strongly absorbs light within the first wavelength band and the second aperture is filled with a semiconductor material that strongly absorbs fight within the second wavelength band. The unit cell can include more apertures optimized to channel and absorb other predetermined wavelength bands.

Any of these aperture array structures or grating structures described below can be further adapted for light circulation or weaving. Devices that can be formed from such aperture array structures include polarizers, wavelength filters, wavelength sensitive channeling devices, light storage, memory, or controlling devices, wavelength and/or polarization sensitive photodetectors and polarization sensors.

The present invention also relates to polarization-tunable enhanced transmission sub-wavelength (PETS) gratings that can be tuned to selectively transmit a predetermined polarization state or to simultaneously enhance transmission of both TM and transverse-electric (TE) radiation. The present invention also relates to enhanced transmission sub-wavelength gratings that include structure that supports CMs, including hybrid cavity modes to produce light-circulating or light-weaving structures, depending on the angle of incident radiation. The gratings of the present invention advantageously have a small form factor, are easy to fabricate, and, consequently, are easy to integrate into devices requiring polarization-tunable transmission. Accordingly, the present invention further relates to devices that include any of the sub-wavelength gratings of the present invention.

A grating for enhancing transmission of incident electromagnetic radiation at a predetermined wavelength of the present invention includes a grating structure adapted to preferentially support cavity modes for coupling to and enhancing transmission of a transverse-electric (TE) polarization state of incident electromagnetic radiation. The grating structure includes a plurality of wires arranged with a periodicity that is equal to or less than the predetermined wavelength; and a groove between each adjacent pair of the plurality of wires. The groove includes a width between the wires and a height, wherein the groove is filled with a dielectric material having a dielectric constant equal to or greater than 1.

In one embodiment of any of the grating structures of the present invention, the dielectric constant is greater than or equal to 1.2. In another embodiment, the dielectric constant is greater than or equal to 2.0. In yet another embodiment, the dielectric constant is greater than or equal to 10, preferably greater than or equal to 14.

Any of the grating structures of the present invention can include an aspect ratio of the groove width to the periodicity in a range of at least 1 to less than or equal to 10.

Any of the grating structures of the present invention can include wires that are formed from any highly conductive material, including one or more of aluminum, silver, gold, copper and tungsten.

Any of the grating structures of the present invention can be superposed on a substrate, which can include a plurality of layers, preferably where at least two layers are of different materials. Any of the substrates in the gratings of the present invention can include one or more of silica, silicon, silicon dioxide, Ge, GaAs, InP, InAs, AlAs, GaN, InN, GaInN, GaAlAs, lnSb, fused silica, sapphire, quartz, glass, and BK7.

The dielectric material in the grooves of any of the grating structures of the present invention can include at least one of silica, silicon, silicon dioxide, silicon nitride, alumina, an elastomer, a crystalline powder, a semiconductive material, crystalline ditantalum pentoxide, polycrystalline ditantalum pentoxide, crystalline hafnium oxide and polycrystalline hafnium oxide.

The present invention further includes a grating for enhancing transmission of incident electromagnetic radiation at a predetermined wavelength including a grating structure adapted to preferentially support cavity modes for simultaneously coupling to and enhancing transmission of a transverse-electric (TE) polarization state and a transverse-magnetic (TM) polarization state of incident electromagnetic radiation at the predetermined wavelength. The grating structure includes a plurality of wires arranged with a periodicity that is equal to or less than the predetermined wavelength; and a groove between each adjacent pair of the plurality of wires, the groove including a width between the wires and a height, and wherein the groove is filled with a dielectric material having a dielectric constant equal to or greater than 1.

One embodiment of the grating has a transmission efficiency of each of the TE and TM polarization state of at least 80%.

The present invention further provides a grating including a grating structure adapted to preferentially support TE-excitable cavity modes at a first predetermined wavelength for coupling to and enhancing transmission of a transverse-electric (TE) polarization state of incident electromagnetic radiation at the first predetermined wavelength and to preferentially support TM-excitable cavity modes at a second predetermined wavelength for coupling to and enhancing transmission of a transverse-magnetic (TM) polarization state of incident electromagnetic radiation at the second predetermined wavelength. The grating structure includes: a plurality of wires arranged with a periodicity that is equal to or less than the predetermined wavelength; and a groove between each adjacent pair of the plurality of wires, the groove including a width between the wires and a height. The grating structure is further adapted to reflect the TM polarization state at the first predetermined wavelength and to reflect the TE polarization state at the second predetermined wavelength.

The present invention still further provides a grating for enhancing transmission of incident electromagnetic radiation at a predetermined wavelength that includes a grating structure adapted to preferentially support cavity modes for coupling to and simultaneously enhancing transmission of a TE-polarization state and a TM-polarization state at the predetermined wavelength. The grating structure includes a grating period that extends from a leading edge of a first wire in one of the sets to a leading edge of a first wire in the next set, so that a set of at least two wires and two grooves occurs within the grating period; i.e., the grating period includes two grooves per period. A first groove is between an adjacent pair of wires within each the set. Each first groove is associated with a first set of grating parameters including a first groove width, a first groove dielectric constant, and a first groove height. A second groove is between each repeating set of wires. The second groove is also associated with a second set of grating parameters including a second groove width, a second groove dielectric constant, and a second groove height.

In one embodiment, at least one of the first grating parameters differs from the corresponding second grating parameter by an amount that is sufficient to prevent the production of cavity modes in adjacent grooves that have overlapping transmission spectra.

In another embodiment, either the first width differs from the second width or the first dielectric constant differs from the second dielectric constant or both width and dielectric constant differ by a combined amount sufficient to prevent the production of cavity modes in adjacent grooves that have overlapping transmission spectra.

A metal-semiconductor-metal detector device of the present invention includes a sensor for measuring an intensity of a transmitted TM and TE polarization state respectively at a predetermined wavelength and a grating for enhancing transmission of incident electromagnetic radiation at the predetermined wavelength that includes a grating structure adapted to preferentially support cavity modes for coupling to and simultaneously enhancing transmission of the TE-polarization state and the TM-polarization state at the predetermined wavelength and to preferentially transmit the TE-polarization state through the first grooves, and the TM-polarization state through the second grooves. The grating structure includes a grating period that extends from a leading edge of a first wire in one of the sets to a leading edge of a first wire in the next set, so that a set of at least two wires and two grooves occurs within the grating period; i.e., the grating period includes two grooves per period. A first groove is between an adjacent pair of wires within each the set. Each first groove is associated with a first set of grating parameters including a first groove width, a first groove dielectric constant, and a first groove height. A second groove is between each repeating set of wires. The second groove is also associated with a second set of grating parameters including a second groove width, a second groove dielectric constant, and a second groove height.

The present invention further includes a grating for enhancing transmission of incident electromagnetic radiation at a predetermined wavelength including a grating structure adapted to preferentially support cavity modes for coupling to and enhancing transmission of a predetermined polarization state at the predetermined wavelength, and for inducing light circulation or light weaving of the transmitted predetermined polarization state at the predetermined wavelength. The grating structure includes: a grating period having at least two grooves per grating period, a set of at least two wires occurring within each period, the grating period extending from a leading edge of a first wire in one of the sets to a leading edge of a first wire in the next one of the sets. The grating structure includes a first groove between an adjacent pair of wires within each set, where each first groove is associated with a first set of grating parameters including a first groove width, a first groove material having a first dielectric constant, and a first groove height. A second groove is between each adjacent set of wires, where the second groove is associated with a second set of grating parameters including a second groove width, a second groove material having a second dielectric constant, and a second groove height.

In one embodiment, one or more of the first grating parameters differs from the corresponding one or more of the second grating parameters by an amount that is sufficient to produce cavity modes in adjacent grooves that have overlapping transmission spectra.

In another embodiment, the first groove dielectric constant differs from the second groove dielectric constant and the first groove width differs from the second groove width.

A light storage device of the present invention includes an embodiment of the light circulating grating of the present invention.

The present invention further provides a method of fabricating a waveband filter, the waveband filter including a grating structure adapted to enhance transmission of both transverse magnetic (TM) and transverse electric (TE) polarized incident electromagnetic radiation within a waveband that includes a predetermined wavelength, and a substrate on which the grating structure is superposed. The grating structure includes a groove dielectric constant ∈_{groove}, a grating period Λ, a groove width, and a groove height. The method includes the following steps:
selecting the substrate with an index of refraction nₛ and the grating period Λ such that a first order diffraction occurs at a wavelength λ equal to Λ/nₛ that is less than the predetermined wavelength;
selecting an initial value for the groove width, the groove height and the groove dielectric constant that produce a transmission curve for each of the TM and the TE polarized radiation that at least partially falls within the waveband;
iteratively varying a value for the groove height from the initial value and determining a wavelength of a transmission intensity maximum of the TM-polarization state at the iterative values for the groove height to determine an optimal groove height for enhancing transmission of the TM-polarization state at the predetermined wavelength;
for the optimal groove height and the initial value of the groove dielectric constant, vary a value for the groove width from the initial value until a transmission intensity maximum of the TE-polarization state is aligned with the transmission intensity maximum of the TM-polarization state at the predetermined wavelength to obtain an optimal groove width; and
fabricating the grating structure having the initial value of groove dielectric constant ∈_{groove}, the optimal groove height, and the optimal groove width on the substrate.
   In one embodiment, the method further includes determining an aspect ratio defined as groove height divided by groove width and varying the aspect ratio, groove height and groove width to adjust a width of the waveband and to align the TM- and TE-polarization transmission curves to the predetermined wavelength.

As a result, the present invention provides polarization-tunable enhanced transmission sub-wavelength (PETS) gratings that can be tuned to selectively transmit a predetermined polarization state or to simultaneously enhance transmission of both TM and transverse-electric (TE) radiation. In some embodiments, these PETS gratings are further adapted for light circulation or weaving. The present invention also provides enhanced transmission sub-wavelength gratings that include structure that supports cavity modes, including hybrid cavity modes, and devices that include any of the sub-wavelength gratings of the present invention. Such devices include polarizers, wavelength filters, light storage, memory, or controlling devices, and metal-semiconductor-metal photodetectors and polarization sensors.

Although illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

### BRIEF DESCRIPTION OF THE DRAWINGS

FIG. 1 is an illustration of enhanced transmission using a Poynting vector to represent light channeling through a cross-section of a single-groove-per-period grating.

FIG. 2 is a cross-sectional view of one embodiment of a single-groove-per-period grating structure of the present invention.

FIG. 3 is a top plan view of the embodiment of FIG. 2.

FIG. 4 is three-dimensional view of another embodiment of a single-groove-per-period grating of the present invention.

FIGS. 5A-5C are schematic representations of three different embodiments of a grating structure of the present invention for enhanced transmission of a predetermined polarization state at a predetermined wavelength.

FIG. 6 is a cross-sectional view of a representation of a grating structure of the present invention that can be adapted for any one of the embodiments of FIGS. 5A-5C.

FIG. 7 is a graphical representation of a dependence of peaks in transmission of different order modes for TE- and TM-polarization states on incident energy and groove width for an embodiment of a single groove per period grating structure of the present invention.

FIG. 8 is a transmission/reflectance plot for an embodiment of a grating structure of the present invention for simultaneous enhanced transmission of both TE and TM-polarized light at a predetermined wavelength.

FIG. 9 is a transmission/reflectance plot for an embodiment of a grating structure of the present invention for enhanced transmission of TE-polarized light at one predetermined wavelength and TM-polarized light at another predetermined wavelength.

FIGS. 10-12 are transmission/reflectance plots for particular embodiments of the grating structure of FIG. 5C for use as wavelength filters optimized at different predetermined wavelengths.

FIG. 13A is a cross-sectional view of an embodiment of a grating structure of the present invention having more than one groove per period.

FIG. 13B is a transmission plot of TE and TM-polarized states for a sub-grating structure of the grating structure of FIG. 13A.

FIG. 14 is a transmission plot of TB and TM-polarized states for another sub-grating structure of the grating structure of FIG. 13A.

FIG. 15 is a transmission plot of TE and TM-polarized states for an embodiment of the grating structure of FIG. 13A.

FIG. 16A is an SIBC modeled magnetic field density for a TM-polarized cavity mode (“CM”) in the embodiment corresponding to FIG. 15.

FIG. 16B is a Poynting vector representation of a TM-polarized CM in the embodiment corresponding to FIG. 15.

FIG. 17A is an SIBC modeled magnetic field density for a TE-polarized CM in the embodiment corresponding to FIG. 15.

FIG. 17B is a Poynting vector representation of a TE-polarized CM in the embodiment corresponding to FIG. 15.

FIG. 18 is a pictorial representation of a metal-semiconductor-metal device including an embodiment of the grating structure of the present invention.

FIGS. 19A and 19B are Poynting vector representations of an embodiment of a grating structure adapted to support light circulation in accordance with the present invention.

FIG. 20 is a Poynting vector representation of an embodiment of a grating structure adapted to support light weaving in accordance with the present invention.

FIG. 21 is a schematic representation of an embodiment of a device for light storage formed in accordance with the present invention.

FIG. 22 is a cross-sectional view of an embodiment of a layered grating structure formed in accordance with the present invention.

FIG. 23 is a flow chart representation of an embodiment of a method of the present invention.

FIG. 24 is a perspective view of a portion of an embodiment of a grating structure formed in accordance with the present invention providing a description of a coordinate system used to describe the grating structure.

FIG. 25 is a plot of the transmittance of the TM-polarized and TE-polarized CMs derived using an SIBC algorithm according to a method of the present invention for an embodiment of a grating structure of the present invention.

FIGS. 26 and 27 are plots of a full ω-k reflectance and transmittance profile of the TM-polarized and TB-polarized. CMs, respectively, derived in accordance with a method of the present invention for the embodiment corresponding to FIG. 25.

FIGS. 28 and 29 are representations of the magnetic field and electric field intensities of the 25.188 GHz TM-polarized and TE-polarized CMs, respectively, derived in accordance with a method of the present invention for the embodiment corresponding to FIG. 25.

FIG. 30 is a representative plot of the experimental transmissivity data obtained for a sample of a grating structure formed in accordance with the present invention, which corresponds to the modeled grating structure described by FIGS. 25-29.

FIG. 31 is a cross-sectional view of an embodiment of a grating structure formed in accordance with the present invention.

FIG. 32 is a ω-k reflectance and transmittance profile for TE-polarized CMs for an embodiment of a grating structure of the present invention.

FIG. 33A is a ω-k reflectance and transmittance profile for TE-polarized CMs for another embodiment of a grating structure of the present invention that supports π resonances.

FIG. 33B is a Poynting vector representation of the embodiment corresponding to FIG. 33A.

FIGS. 34A and B are TE and TM Poynting vector representations of a light-circulating embodiment of a grating structure of the present invention.

FIG. 35 is a Poynting vector representation of a light-weaving embodiment of a grating structure formed in accordance with the present invention.

FIG. 36 is a schematic representation of a top view of an embodiment of an aperture array structure formed in accordance with the present invention.

FIG. 37 is a cross-section through the embodiment of the aperture array structure of FIG. 36.

FIG. 38 is a schematic representation of a cross-sectional view of an aperture array superstructure composed of layers of aperture array structures formed in accordance with the present invention.

FIG. 39 is a perspective view of a schematic representation of a solar cell device formed in accordance with the present invention.

FIG. 40 is a cross-sectional view through a single solar cell of the device shown in FIG. 39.

FIG. 41 is a Poynting vector representation and of optical cavity modes tuned to concentrate all of the light into a cavity in which one of the solar cells of FIG. 40 is located.

### DETAILED DESCRIPTION

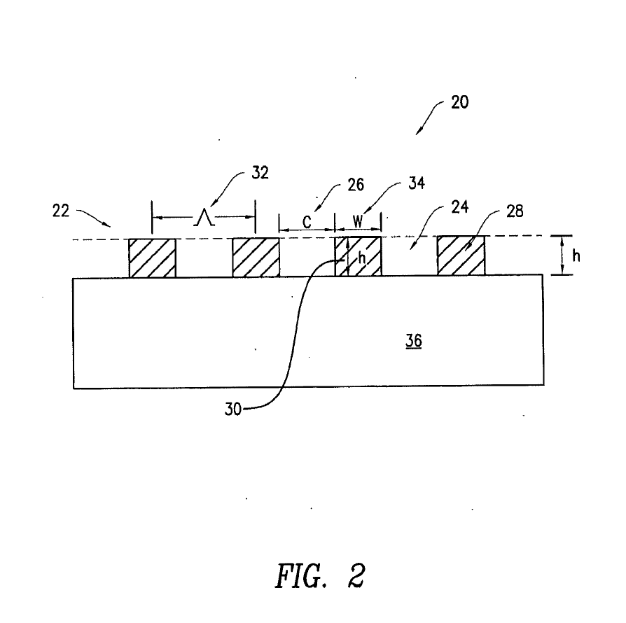

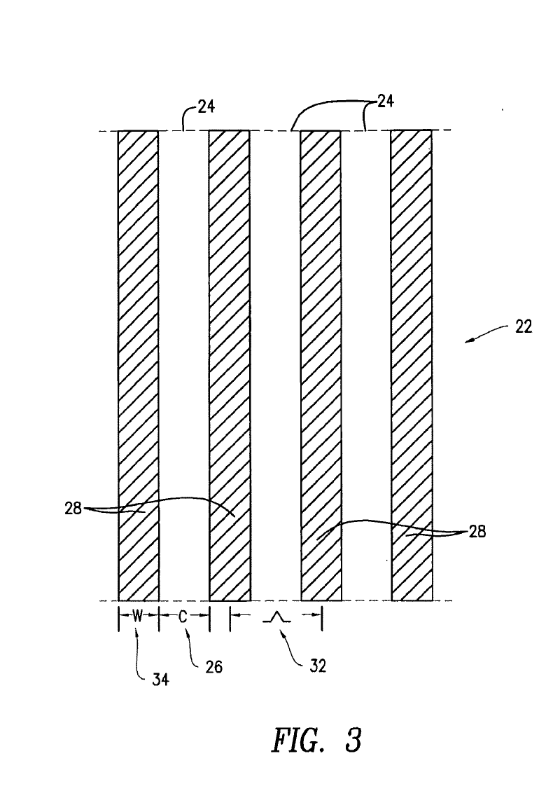

Referring to FIGS. 2-4, one embodiment of the sub-wavelength gratings formed in accordance with the present invention includes a polarization-tunable enhanced transmission sub-wavelength (PETS) grating 20 having a grating structure 22 that enhances transmission of a predetermined polarization state for a predetermined wavelength of incident radiation. The grating structure 22 includes a plurality of grooves 24 of refractive index n_{groove} (or dielectric constant ∈_{groove}, where n_{groove}=\sqrt{∈_{groove}}) equal to or greater than 1 and having a width c 26, and a plurality of wires 28 defining a groove height 30 arranged with a center-to-center period Λ 32 that is less than the predetermined wavelength.

In one embodiment, as shown in FIGS. 2-4, the grating structure includes a single groove 24 per period Λ 32.

The grating structure 22, which is preferably superposed on a substrate 36, but may optionally be encased within a substrate material, is structured to support cavity modes (“CMs”) at a particular predetermined wavelength.

The grating structures of the present invention are optimized to support cavity modes at a particular predetermined wavelength, preferably within a particular band that includes the predetermined wavelength. One of ordinary skill in the art will recognize that the particular examples of grating structures provided herein can have dimensions sealed appropriately to a particular wavelength range of interest and include the corresponding appropriate materials for the wires and grooves and substrate material.

In particular, in various embodiments, any of the grating structures of the present invention can be adapted to support resonant modes at a predetermined wavelength between: 1 nm and 400 nm; 400 nm and 700 nm; 0.7 microns and 100 microns; 100 microns and 1 mm; and 1 mm and 400 mm.

The substrate in any of the gratings of the present invention can be composed of any dielectric suitable for the particular application, including any one or more of glass such as BK7, silica, fused silica, silicon dioxide (SiO₂), silicon (Si), (including crystalline, poly-crystalline or amorphous), air, sapphire, quartz, or any or more semiconductor material, including III-IV and ternary compound semiconductors, including Ge (Germanium), Gallium Arsenide (GaAs), Indium Phosphide (InP), Indium Arsenide (InAs), Aluminum Arsenide (AlAs), Gallium Nitride (GaN), Indium Nitride (InN), Indium Antimonide (In Sb), Gallium Indium Arsenide (GaInAs), Gallium Indium Nitride (GaInN), Gallium Aluminum Arsenide (GaAlAs), and mercury cadmium telluride (HgCdTe).

The substrate can include more than one layer. Each of the multiple layers can be composed of a different material.

In one embodiment, the substrate includes an anti-reflective material.

Cavity modes (CMs), as referred to herein, are resonant modes produced within the grooves of a grating structure that satisfy the well-known Fabry-Perot resonance condition within the grooves. CMs include resonant modes produced by waveguide modes (WGs) of incident transverse-electric (TE) polarized radiation; and resonant modes produced by either WGs or vertically-oriented surface plasmons (VSPs) on the walls of the grooves of incident transverse-magnetic (TM) polarized radiation. The term “cavity mode”, in referring to the light circulating structures of the present invention also includes hybrid cavity modes that induce phase resonances.

TM-polarized (p-polarized) radiation is defined as electromagnetic radiation oriented so that its magnetic field is parallel to the grating wires. TE-polarized (s-polarized) radiation is electromagnetic radiation oriented so that its electric field is parallel to the grating wires.

The enhanced transmission gratings of the present invention are “sub-wavelength” gratings for enhancing transmission of incident electromagnetic radiation at a predetermined wavelength. “Sub-wavelength,” as referred to herein, means that a periodicity of the wires of the grating is equal to, or on the order of, or less than the predetermined wavelength, so that the spacing between the wires is less than the predetermined wavelength.

The grating structures and gratings formed in accordance with the present invention, which enhance transmission of one or more polarization states to produce grating devices for various applications, are collectively referred to herein for convenience as “polarization-tunable enhanced transmission sub-wavelength” (“PETS”) grating structures and gratings. Use of this acronym is not to be construed in any way as limiting the grating structures of the present invention.

The wires of the present invention, which are also referred to as contacts, can be of any shape, size and of any material and arranged in any geometrical pattern to form a grating structure that preferentially supports CMs for enhancing transmission of a predetermined polarization state at a predetermined incident wavelength to form an embodiment of a grating structure of the present invention. For example, depending on the predetermined polarization state, predetermined wavelength, and desired application, the wires can be of a width that is 1%-95% relative to the period of the particular grating structure and of a height that is 1%-1000% relative to the period of a particular grating structure. The grooves in the grating structure preferably have widths of 1% 1000% relative to the period.

The height “h” as referred to herein refers to a groove height, which is preferably equivalent to an adjacent wire height. However, it is contemplated to be within the scope of the invention to arrange the wires within recesses of a substrate, so that a wire height could be greater than an adjacent groove height. In such cases, the height h referred to herein is the groove height. It is also contemplated to provide different wires having different heights in a multiple-groove-per-period structure. In such cases, the height h referred to herein is a groove height corresponding to one of the adjacent wires.

Alternatively, the grating structures of the present invention can be formed from arrays of holes in thin (metallic) films.

Preferably, the wires in any of the grating structures can include any highly conducting metals, for example, any one or more of gold (Au), silver (Ag), aluminum (Al), copper (Cu), and tungsten.

In one embodiment, each wire has a quadrilateral cross-section such as rectangular, square, or trapezoidal. The intersection between the wires and the substrate is preferably formed of straight edges, but a curved or sloped interface can occur in the manufacturing process. This slight curvature of the interface does not affect the excitation of CMs, but it can shift the energy at which resonance occurs. Such shifts are preferably accounted for in the optimization of the grating structure parameters.

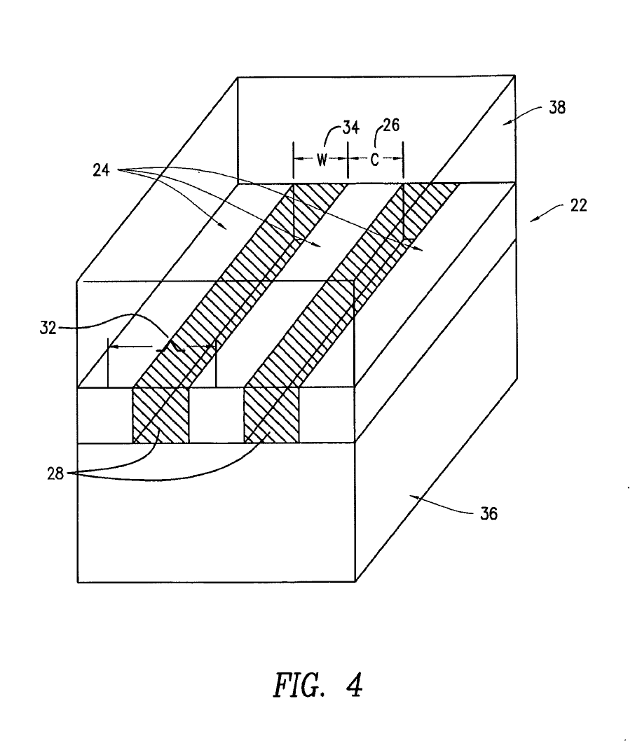

Referring to FIG. 4, in one embodiment, the grating structure 22 can include a material other than air superposed in a so-called “superstrate” layer 38 on top of the wires 28 and grooves 24. The layer 38 preferably includes a passivation or protective layer, and can be composed of materials such as a glass, oxide (e.g., SiO₂), polymer or plastic.

In a preferred embodiment, the grooves 24 are filled with a dielectric material having dielectric constant ∈_{groove}, of at least 1.2, most preferably at least 2. In one embodiment, the dielectric constant ∈_{groove} of the material ranges from 2-20.

In another embodiment, the dielectric constant ∈_{groove} of the material in the grooves is at least 10, preferably at least 14. For example, the material in the grooves can be crystalline or polycrystalline ditantalum pentoxide or crystalline or polycrystalline hafnium oxide. These “high-K” materials, i.e., materials having a high dielectric constant, are particularly advantageous for TE-transmitting radiation, as described herein.

The grooves can be filled with air or with any material useful to the particular application. In one embodiment, the grooves 24 are filled with semiconductor materials, including one or more of silicon (Si), germanium, (Ge) and other III-V semiconductor compounds. The grooves can also be filled with at least one of silica, silicon, silicon dioxide, silicon nitride, alumina, an elastomer, and a crystalline powder.

Any of the grating structures or gratings of the present invention can also be adapted to localize a predetermined polarization state of incident electromagnetic radiation at a predetermined wavelength, and within a particular waveband, within the grating structure or grating.

The present invention is, in part, a result of the Applicants' efforts to accurately model the modes responsible for enhanced transmission in a known one-dimensional (1-D) sub-wavelength grating. Contrary to prior teachings on the subject that reported HSPs as primarily responsible for enhanced optical transmission (BOT), Applicants Crouse and Keshavareddy found and reported in a publication entitled “The role of optical and surface plasmon modes in enhanced transmission and applications, Optics Express, Vol. 13: Iss. 20, pp. 7760-7771 (Oct. 3, 2005) (“Crouse 2005”), the entirety of which is incorporated herein by reference thereto, that HSPs can both strongly inhibit and weakly enhance transmission in such sub-wavelength gratings. Applicants further reported that the predominant effect appeared to be a strong inhibition of transmission and interference with the transmission-enhancing properties of other resonant modes that could contribute to the phenomenon of enhanced transmission.

More recently, Applicants were able to theoretically show that cavity modes (CMs) in a lamellar grating structure can produce enhancements in transmission selectively for one or all polarizations of incident light. In addition, Applicants discovered that the properties of such CM-coupled grating structures (e.g., bandwidth, electromagnetic field profiles) and their dependencies on wavelength, angle of incidence, and structural geometries differ significantly from those of prior-art gratings optimized for HSP-induced enhanced transmission.

The formulation of the dependence of the parameters of a sub-wavelength grating on enhanced transmission was reported in Crouse and Keshavareddy, “Polarization independent enhanced optical transmission in one-dimensional gratings and device applications,” Oplies Express, Vol. 15, No. 4, pp. 1415-127 (Feb. 19, 2007) (“Crouse 2007”), the entirety of which is incorporated herein in reference thereto.

In particular, Applicants have found that it is the cavity modes (CMs) defined herein, e.g., the resonant modes produced by WGs or the cavity mode component of a hybrid mode (consisting of both cavity resonance and surface plasmons resonance) that play the primary role in EOT of TE radiation, i.e., radiation polarized parallel to the metal wires.

Applicants have similarly found that similar cavity resonances can be found for TM radiation, i.e., for radiation polarized perpendicular to the wires, and that these resonances can help channel light through the grooves of the grating structure of the present invention to achieve enhanced optical transmission for this polarization state.

In other words, Applicants found that grating structures can be tailored to selectively support cavity modes corresponding to those modes that satisfy the Fabry-Perot condition inside the grooves, which can be preferentially excited by one or both of TM and TE-polarized radiation. Applicants further found that excitation of these cavity modes at a particular predetermined energy or wavelength can predictably provide enhanced transmission of one or both of TM and TE radiation through the grooves. It has also been found that the energy location of the peak transmission shifts to lower energies as the groove height or the dielectric constant of the groove is increased.

In optimizing the grating structure of the present invention to provide such polarization-tunable enhanced transmission, Applicants have surprisingly found that an essential design parameter in tuning the peaks of enhanced transmission for both TE and TM polarization states, not reported in the prior art, is the spacing between the wires, or the groove width c 26, referring to FIGS. 2-4, e.g. For a given polarization and fixed groove height and period, changes in the groove width alters the number of groove modes, energy at which EOT occurs, and the electromagnetic field distribution inside the grooves.

For TM-polarized light CMs produced in very narrow groove openings, the resonantly enhanced electromagnetic fields is relatively uniform throughout the groove and as the groove width is increased, the field redistributes with high intensity electromagnetic fields remaining close to the groove walls for wide openings. On the other hand, for TE polarization, the electromagnetic fields inside the grooves are concentrated more at the center of the groove, with very little fields on the side walls. As the groove width is increased, more resonance modes start occurring, redistributing the fields into lobes of high field intensities.

These characteristics and dependencies of CMs on the parameters of a grating structure are exploited, as described in more detail later in this specification, to form polarization-tunable enhanced transmission sub-wavelength (PETS) grating structures in accordance with the present invention by adapting and optimizing the grating structure parameters to selectively support the cavity modes that will couple to the predetermined polarization state (TE, TM or both, e.g.) at the predetermined wavelength.

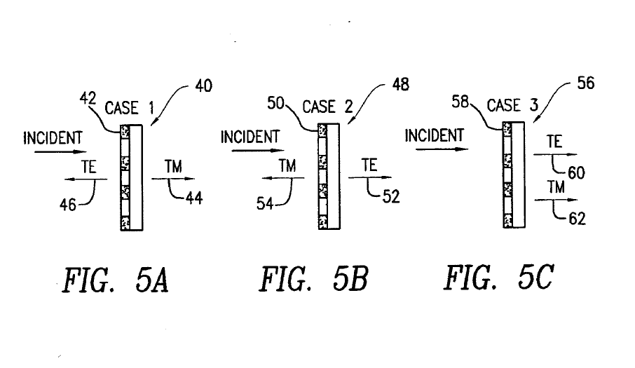

Referring to FIG. 5A, one embodiment 40 of a PETS grating of the present invention includes a grating structure 42 that enhances transmission of TM-polarized radiation 44 at a predetermined wavelength and reflects TE-polarized radiation 46 to provide a “TE-pass” wavelength filter.

Referring still to FIG. 5B, another embodiment 48 of a PETS grating of the present invention includes a grating structure 50 that enhances transmission of TE-polarized radiation 52 at a predetermined wavelength and reflects TM-polarized radiation 54 to provide a “TM-pass” wavelength filter.

Yet another embodiment 56 of a PETS grating of the present invention shown schematically in FIG. 5C includes a grating structure 58 that simultaneously enhances transmission of TE 60 and TM-polarized radiation 62 at a predetermined wavelength.

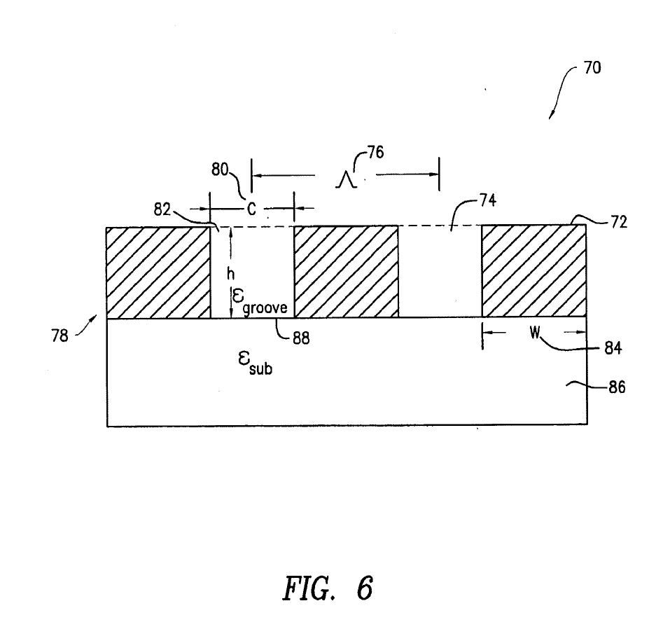

Each grating structure of the PETS gratings shown in FIGS. 5A-5C includes wires of substantially rectangular cross-section formed in a one-dimensional (1D) grating structure that supports cavity modes, as described in further detail below in reference to FIG. 6. In the embodiments shown in FIGS. 5A-5C and 6, the grating structure includes a single groove per period.

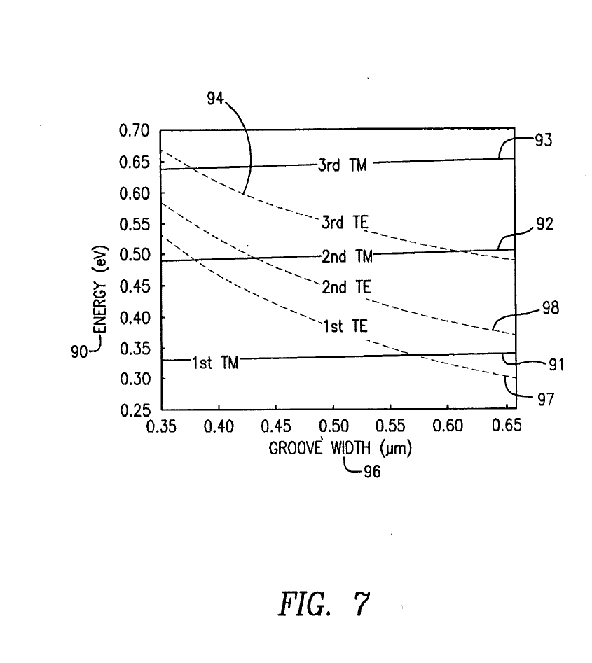

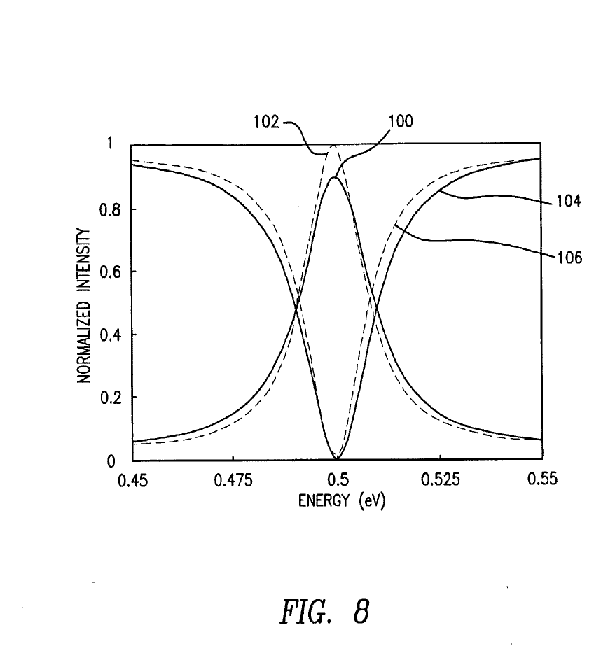

The grating 70 of FIG. 6, includes a plurality of wires 72 arranged in a one groove 74 per period 76 structure 78 adapted to enhance transmission of a predetermined polarization state at a pre-determined wavelength. Each groove has a width c 80 and is filled with a material 88, which can be air or a material of index of refraction k, or dielectric constant ∈_{groove} (where ∈_{groove}=k²), greater than 1. Each wire 72 defines a groove height 82, has a width w 84, and is composed of gold. For the particular examples and plots described with reference to FIGS. 7-8, it is assumed that the grating structure 78 is free-standing; the “substrate” 36 is air.

In one embodiment of the grating 70, the periodicity Λ 76 is 1.75 microns, height h 82 is 1 micron, and silicon, a material having a dielectric constant ∈_{groove} of 11.9, fills the grooves 74. Using the methods of the present invention for modeling PETS gratings, one can generate a plot, as shown in FIG. 7, of the peak wavelength (energy) 90 of transmission for TM-polarized 92 and TE-polarized light 94 as a function of groove width 96 for the grating structure 78 having these parameters, with groove width varying from 0.35 microns to 0.66 microns. In FIG. 7, the 1st TM 91, 2nd TM 92, and 3rd TM 93 curves correspond to the three different orders of cavity mode resonance that occur when the grating is illuminated by light polarized parallel to the grid. Similarly, the 1st TE 97, 2nd TE 98, and 3rd TE 94 curves correspond to the three different orders of cavity mode resonance that occur when the grating is illuminated by light polarized perpendicular to the grid.

As can be seen from FIG. 7, the peak at which EOT occurs moves to higher energies for TM-polarized light and lower energies for TE-polarized light. It is also seen that for the particular parameters of the grating structure 78 chosen (Λ 76 of 1.75 microns, height h 82 of 1 micron, and grooves of 11.9), an energy of 0.5 eV (Λ=2.5 μm) and a groove width 80 of 0.615 microns correspond to a point of intersection of the two curves 92 and 94. Therefore, an embodiment of a grating structure of the present invention that supports CMs for simultaneous LOT of TE and TM polarization at the same predetermined wavelength of 2.5 microns (μm), as described by FIG. 5C is achieved.

In one embodiment of the grating structure of the present invention, the dielectric material filling the grooves has a dielectric constant ∈_{groove} of at least 10, preferably at least 14. Applicants have determined that for grooves having a high dielectric constant, the grating structure of the present invention: provides TE-polarization enhanced transmission at lower energies than is possible without their use; inhibits TM-polarization transmission in gratings when there is not a TE-polarized CM excited; and allows alignment of TE-polarized and TM-polarized CMs at lower energies. Accordingly, a preferred embodiment of the grating structure that is tuned for simultaneous TE and TM transmission includes a dielectric constant ∈_{groove} of at least 10, preferably at least 14.

FIG. 8 shows a plot of the TM zero-order transmission 100 and TE zero-order transmission 102 curves as a function of energy for this embodiment. The TM reflectance 104 and TE reflectance 106 curves are also plotted for comparison.

Referring to FIG. 8, it can be concluded that for unpolarized incident light with an equal contribution from both polarization states (50% TM, 50% TE), as high as 94% of the incident light can be transmitted into a substrate 86 (FIG. 6). Accordingly, the methods of the present invention can be applied to effect significant design improvements in a variety of optoelectronic devices, particularly those requiring detection of polarization-independent radiation.

Starting again with an embodiment of the grating structure 78 shown in FIG. 6 having periodicity Λ 76 of 1.75 microns, height h 82 of 1 micron, and with silicon, ∈ of 11.9, filling the grooves 74, an embodiment of the grating structure 78 can be obtained by optimizing the groove width c 80 for enhancing transmission of either a TE- or TM-polarized radiation at a predetermined wavelength. In particular, by plotting the peaks of transmission for zero-order TM-polarized Eight and the dips of transmission for TE-polarized light as a function of groove width, the optimum groove width (point of intersection of the two curves) can be obtained to provide the PETS grating 40, in accordance with FIG. 5A, that enhances transmission of TM-polarized radiation 44 at a predetermined wavelength. Likewise, by plotting the peaks of transmission of TE-polarized light and dips of transmission of TM-polarized light, the optimum groove width can be determined to provide the PETS grating 48 in accordance with FIG. 5B, for enhancing transmission of TE-polarized radiation 44 at a predetermined wavelength.

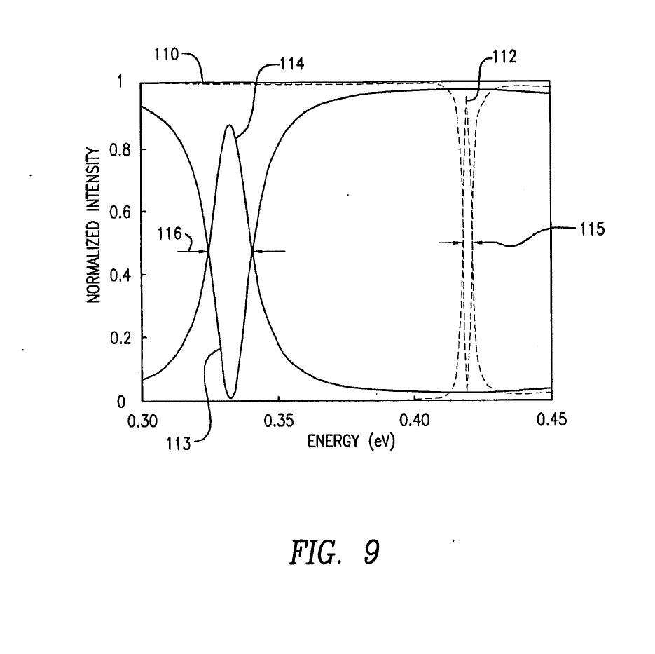

In one particular embodiment, a groove width of 0.45 microns is chosen. FIG. 9 provides plots of the reflectance 110 and transmittance 112 of TE-polarized radiation, and of the reflectance 113 of and transmittance 114 of TM-polarized radiation as a function of incident energy of radiation. It can be seen from FIG. 9, that the grating structure 78 having these parameters (c of 0.45 microns, Λ 76 of 1.75 microns, height h 82 of 1 micron, and with silicon, c of 11.9, filling the grooves 74) is adapted to preferentially enhance transmission of TM-polarized light, as shown in FIG. 5A, for the predetermined wavelength of 3.729 microns (hw=0.333 eV). In another embodiment of the grating 70 having the same configuration and structural parameters, the structure 78 is adapted to enhance transmission of TE-polarized light, as shown in FIG. 5B, for the predetermined wavelength of 2.992 microns (hw=0.415 eV).

Accordingly, grating structure 78 having parameters c of 0.45 microns, Λ 76 of 1.75 microns, height h 82 of 1 micron, and c of 11.9, also represents a grating structure that provides enhanced transmission of TM-polarized light at a first predetermined wavelength (0.45 microns in this example) and enhanced transmission of TE-polarized light at a second predetermined wavelength (3.729 microns in this example).

Referring to FIG. 9, even though the line-widths of the peak transmissions for TE 115 and TM-polarized radiation 116 for the structure are markedly different, it is possible to design narrow or broad peaks by changing a groove aspect ratio, defined herein as a groove height divided by groove width, depending on the application of interest. For example, photodetectors generally require a broad transmission peak, while wavelength filters may require narrow or broad transmission peaks depending on if they are being used as wavelength selectors or band-pass filters.

In a preferred embodiment, the aspect ratio is in a range of at least about 1 to less than about 10.

The PETS grating structures of the present invention can be used for many device applications including polarizers and wavelength filters. A preferred embodiment of a polarizer or wavelength filter firmed in accordance with the present invention includes a PETS grating structure having only one groove per period, as described in reference to FIGS. 2-4, 5A-C and 6.

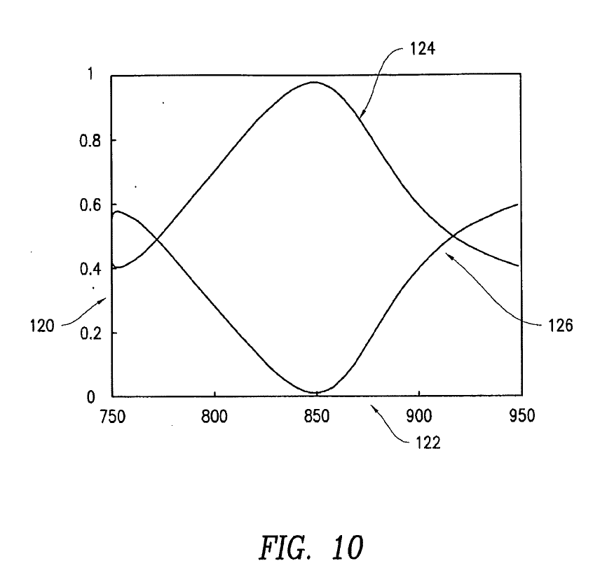

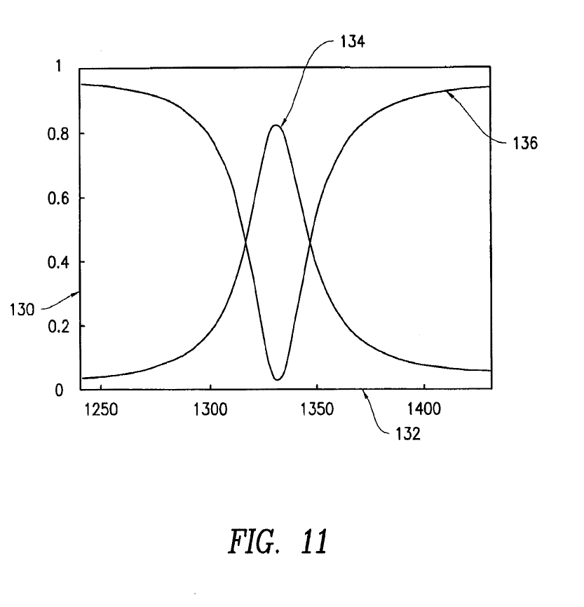

Examples of embodiments of narrow band filters formed from the PETS grating structures of the present invention optimized to simultaneously transmit both TE and TM incident radiation, as described in reference to FIG. 5C, are provided in FIGS. 10-12.

In particular, FIG. 10 provides a plot of normalized intensity 120 as a function of wavelength 122 for one embodiment of a narrow band optical wavelength filter formed in accordance with the present invention, optimized for enhanced transmission at of both TM and TE-polarized light at 850 nanometers (nm). The total transmission 124 and total reflection 126 curves for unpolarized incident radiation show that as high as 95% of un-polarized light can be transmitted into the substrate. In this embodiment of a 1-D periodic grating structure, in reference to FIG. 6, the wires 72 are composed of gold, the grating has a period 76 of Λ=530 nm, the groove spacing 80 between the wires 72 is w=333 nm, and the height 82 defined by the metal contacts is h=490 nm. The grating structure 78 is positioned on top of substrate 86 of SiO₂, and the space between the wires is filled with dielectric material 88, SiO₂.

FIG. 11 provides a plot of normalized intensity 130 as a function of wavelength 132 for one embodiment of a narrow band optical wavelength filter formed in accordance with the present invention, optimized for enhanced transmission at of both TM and TE-polarized light at the telecommunication wavelength of 1330 nm. The total transmission 134 and total reflection 136 curves for unpolarized incident radiation show that as high as 82% of un-polarized light can be transmitted into the substrate. In this embodiment of a 1-D periodic grating structure, in reference to FIG. 6, the wires 72 are composed of gold, the grating has a period 76 of Λ=850 nm, the groove spacing 80 between the wires 72 is w=260 nm, and the height 82 defined by the metal contacts is h=647 nm. The grating structure 78 is positioned on top of substrate 86 of SiO₂, and the space between the wires is filled with dielectric material 88, silicon.

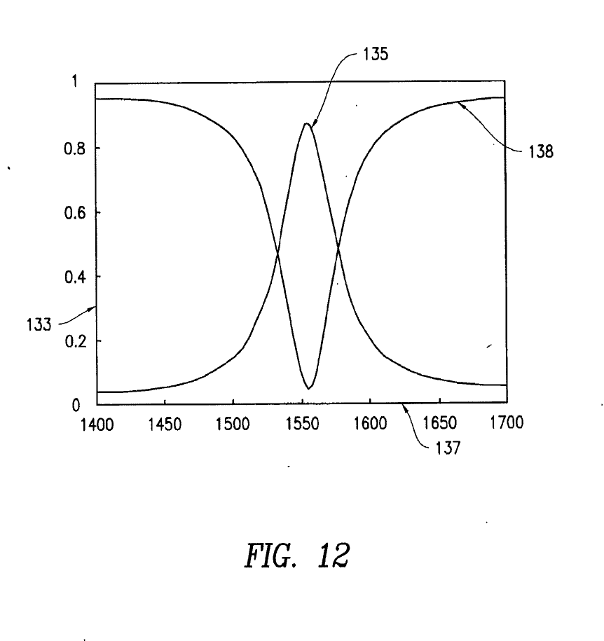

FIG. 12 provides a plot of normalized intensity 133 as a function of wavelength 137 for one embodiment of a narrow band optical wavelength filter formed in accordance with the present invention, optimized for enhanced transmission at of both TM and TE-polarized light at the telecommunication wavelength of 1550 nm. The total transmission 135 and total reflection 138 curves for unpolarized incident radiation show that as high as 82% of un-polarized light can be transmitted into the substrate. In this embodiment of a 1-D periodic grating structure, in reference to FIG. 6, the wires 72 are composed of gold, the grating has a period 76 of Λ=910 nm, the groove spacing 80 between the wires 72 is w=270 nm, and the height 82 defined by the metal contacts is h=575 nm. The grating structure 78 is positioned on top of substrate 86 of SiO₂, and the space between the wires is filled with dielectric material 88, silicon.

The PETS grating structures of the present invention adapted to support CMs produce within the grooves as described herein have a high degree of wavelength, bandwidth and polarization tunability and can, with the use of wires composed of low loss metals, and grooves and substrate materials composed of low-loss dielectrics, transmit close to 100% of the desired polarization component of the incident light.

In particular, in one embodiment of a PETS grating structure for enhanced transmission of either TE or TM polarization at a predetermined wavelength, at least 60% of incident TE or TM radiation respectively at the predetermined wavelength is transmitted.

In another embodiment of a PETS grating structure for enhanced transmission of either TE or TM polarization at a predetermined wavelength, at least 80% of incident TE or TM radiation respectively at the predetermined wavelength is transmitted.

In yet another embodiment of a PETS grating structure for enhanced transmission of either TE or TM polarization at a predetermined wavelength, at least 90% of incident TE or TM radiation respectively at the predetermined wavelength is transmitted.

In still another embodiment of a PETS grating structure for enhanced transmission or either TE or TM polarization at a predetermined wavelength, at least 95% of incident TE or TM radiation respectively at the predetermined wavelength is transmitted.

In one embodiment of a PETS grating structure for simultaneous enhanced transmission of TE and TM polarization at a predetermined wavelength, at least 60% of incident TE and TM radiation at the predetermined wavelength is transmitted.

In another embodiment of a PETS grating structure for simultaneous enhanced transmission of TE and TM polarization at a predetermined wavelength, at least 80% of incident TE and TM radiation at the predetermined wavelength is transmitted.

In yet another embodiment of a PETS grating structure for simultaneous enhanced transmission of TE and TM polarization at a predetermined wavelength, at least 90% of incident TE and TM radiation at the predetermined wavelength is transmitted.

In still another embodiment of a PETS grating structure for simultaneous enhanced transmission of TE and TM polarization at a predetermined wavelength, at least 95% of incident TE and TM radiation at the predetermined wavelength is transmitted.

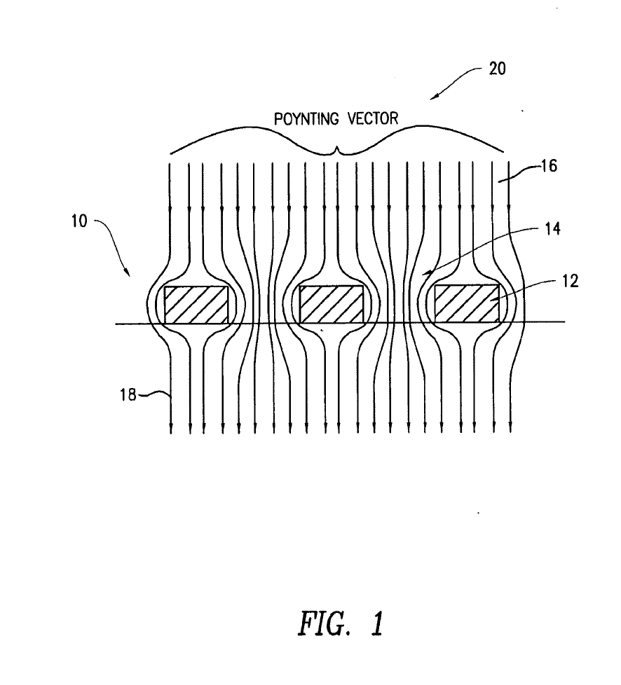

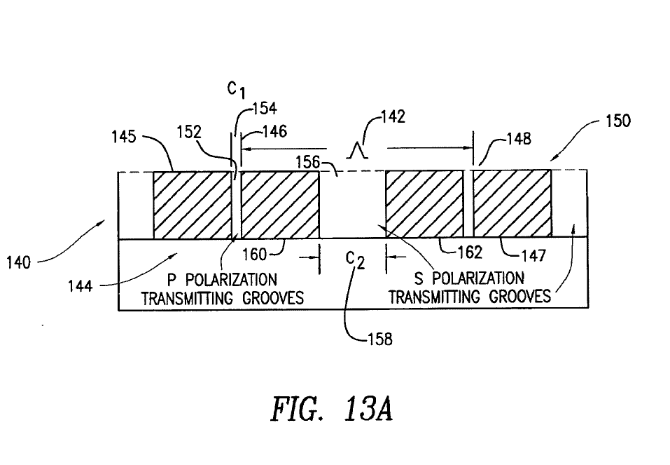

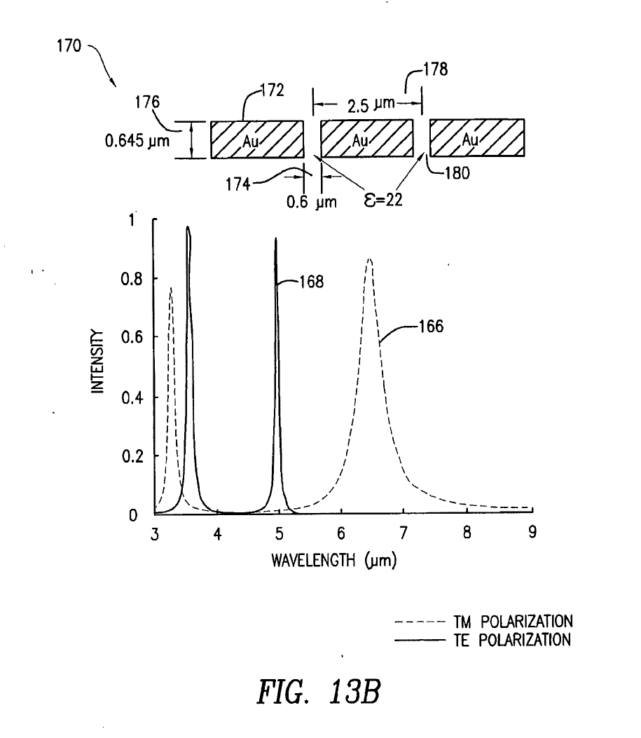

The grating structures of the present invention described above in reference to FIGS. 1-12 and polarizer and wavelength filter devices incorporating these grating structures preferably include grating structures having one groove per period. Referring to FIG. 13A, another embodiment of a PETS grating structure 140 of the present invention includes more than one groove per grating period Λ 142. This type of structure 140 includes a pattern of repeating sets 144 of wires, where each wire in the set can have different characteristics; a first wire 145 in one set 144 is identical to the first wire 147 in the other sets, and so on. The grating period 142 has at least two grooves per grating period, where the grating period 142 extends, for example, from a leading edge 146 of one wire in one set 144 to a leading edge 148 of the corresponding wire in the adjacent set 150. Each set has at least a first groove 152 defined by a first width c₁ 154 and a first dielectric constant ∈_{1groove} between an adjacent pair of wires within each set 144 and a second groove 156 defined by a second dielectric constant ∈_{2groove} and a second width ∈₂ 158 between the last wire 160 in one set 144 and the adjacent first wire 162 in the next set 150 of wires.

The set 144 of wires can be composed of a pattern of wires of different materials, heights, and or shapes. In one embodiment, the grooves are composed of the same material. In other embodiments, the grooves are filled with different materials.

In one preferred embodiment, the grating structure 140 is adapted to preferentially support cavity modes for coupling to and simultaneously enhancing transmission of the TE-polarization state and the TM-polarization state at the same predetermined wavelength.

Preferably, the grating structure is further adapted to preferentially transmit the TM-polarization state through one set of grooves, for example, the first 152 narrower grooves, at the predetermined wavelength, and to preferentially transmit the TE-polarization state through the other set of grooves, for example, the second 156 wider grooves.

In one such embodiment, which is desirable for simple separation of polarized components of incident radiation, one or more of the groove parameters (e.g., groove width, dielectric constant) of the first groove differ(s) from that of the second groove by an amount sufficient to prevent the production of neighboring CMs that have overlapping shoulders within their transmission spectra. In one embodiment, only the groove widths differ, e.g., the first groove width 154 and second groove width 158 in FIG. 13A. Applicants surprisingly discovered that such overlap, rather than broadening the waveband of enhanced transmission as expected, creates hybrid coupled modes between the CMs produced in the first and second grooves that are undesirable for some applications. However, as discussed further below in regard to yet another embodiment, these hybrid CMs can advantageously be exploited to create a new so-called “circulating mode,” with unique device applications.

With reference to FIGS. 13-15, an embodiment of the grating structure 140 can be adapted to support CMs in two different grooves 152 and 156 within one period 142 of the grating structure 140 to preferentially transmit the TM-polarization state through one set of grooves, and the TE-polarization state through a second set of grooves. This embodiment can be described as a combination of two simple single-groove-per-period lamellar “sub-gratings,” having the same period 142 but different groove widths and/or dielectric contacts: (c₁, and ∈_{2groove}). A specific example is provided in FIGS. 13-15. FIG. 13B shows the TM-polarization 166 and TE-polarization transmittance 168 for a first sub-grating 170 with Au wires 172, groove width 174 c=0.60m, height 176 h=0.645 μm, period 178 Λ=2.5 μm, dielectric constant 180 ∈_{groove}=22 (which is approximately the dielectric constant for Ta₂O₅) and air for the substrate and superstrate. Those parameters provide a TE-polarized CM at a predetermined λ=5 μm that selectively transmits TE-polarized light.

This TE-polarized mode corresponds to the n=m=1 mode found according to the formula for 100% confined (within the cavity) CMs provided by Equation (2) below:

$$\frac{2 π}{{λ}_{peak}} = {n}_{groove} \sqrt{{( \frac{π n}{h} )}^{2} + {( \frac{π m}{c} )}^{2}} \qquad ( 2 )$$

where n and m are integers and n_{groove} (=\sqrt{∈_{groove}}) is the index of refraction of the dielectric material in the grooves.

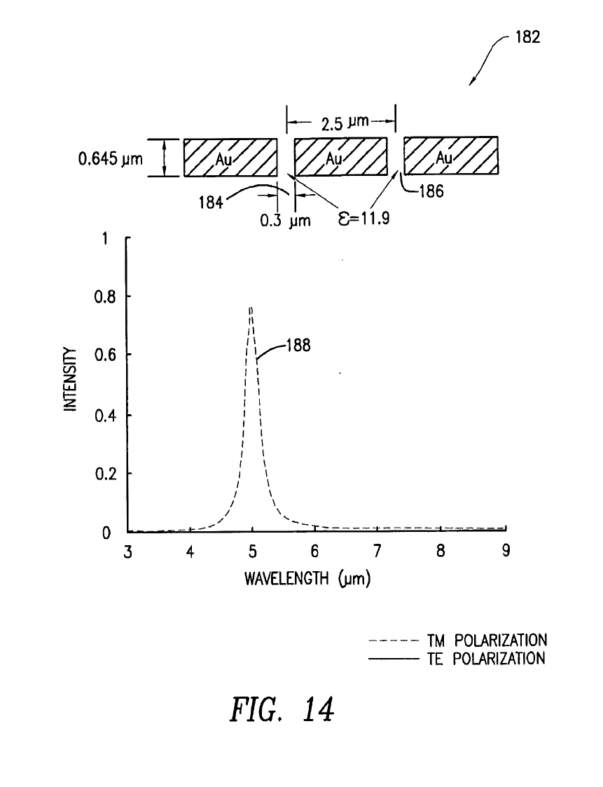

Referring to FIG. 14, if all the grooves are changed to have a width 184 of c=0.3 μm and dielectric constant 186 of ∈_{groove}=11.9 (≈∈_{silicon}) while everything else remains unchanged, to form a second “sub-grating” 182 shown in FIG. 14, this second single-groove-per-period grating has a TM-polarized CM 188 at λ=5 μm (the n=1, m=0 mode of Equation (2)) that selectively transmits TM-polarized light and the TE-polarization transmittance is zero for the wavelength range of 3-9 μm.

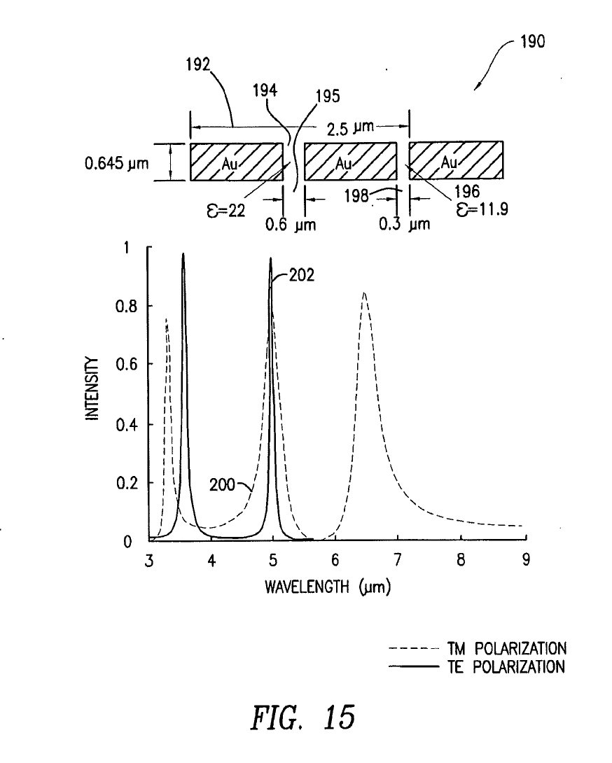

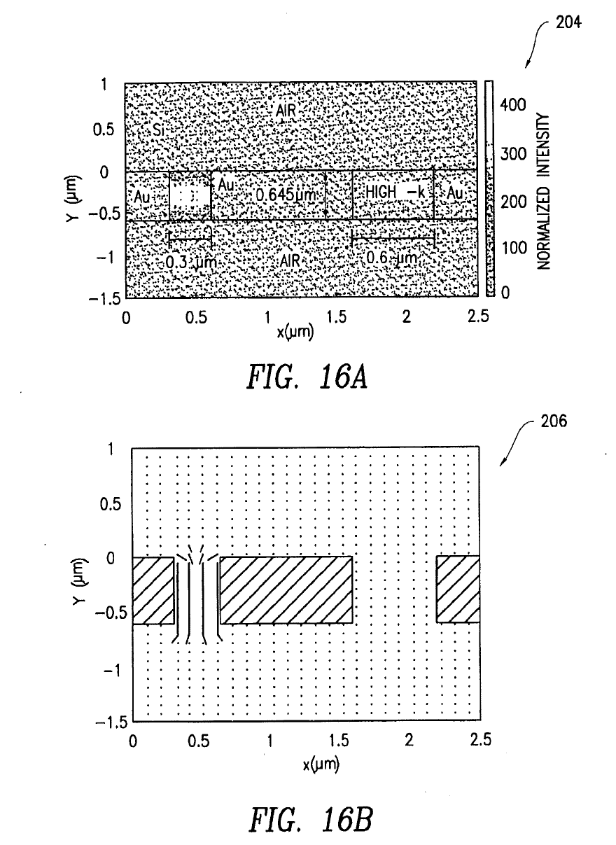

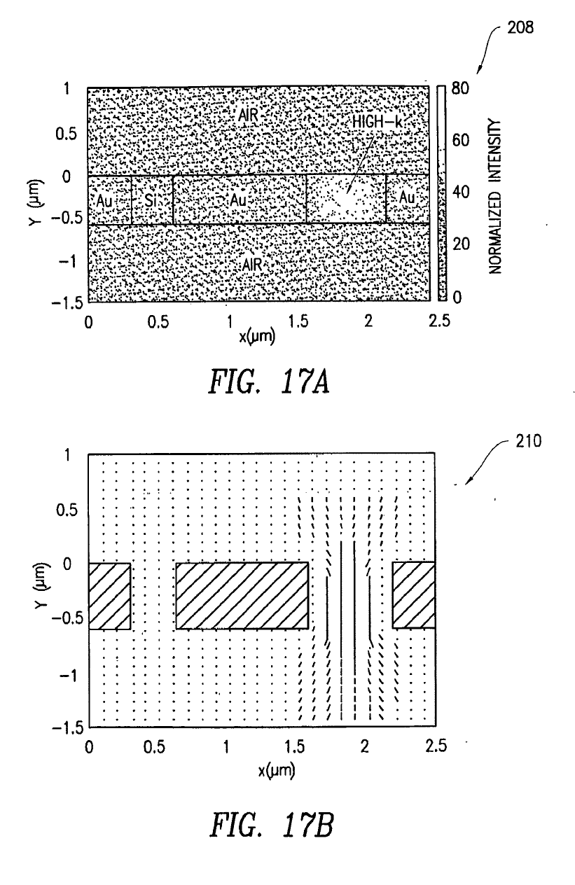

Referring to FIG. 15, if these two gratings 170 and 182 are combined to form the grating structure 190 with two grooves per grating, so that within one period 192 of Λ=2.5 μm, there is one groove 194 with width 195 c=0.6 μm and ∈_{1groove}=22 and one groove 196 with 198 c=0.3 μm and ∈_{2groove}=11.9, the performance can be predicted. The transmittance of such a grating structure is approximately the normalized sum of the transmittance of the two constituent single-groove-per-period gratings shown in FIGS. 13B and 14, as long as there are no phase resonances produced, as discussed below. The TM-polarized light at λ=5 μm is transmitted through the narrower set of grooves, as described by field density 204 and Poynting vector plot 206 in FIGS. 16A and 16B respectively. The TE-polarized 202 light at λ=5 μm is transmitted through the wider set of grooves as described by the field density 208 and Poynting vector plot 210 in FIGS. 17A and 17B respectively. The normalized sum of the transmittances of the constituent single-groove-per-period gratings provides a good approximation of the transmittance of an embodiment of the multiple-groove-per period grating of the present invention for enhanced transmission and separation of both TM and TE polarization states, as long as the grating structure is adapted to preferentially support TM-polarized and TE-polarized CMs that are spaced far enough apart so that phase interactions do not occur.

Additional multiple-groove-per-period gratings for enhanced transmission and separation of predetermined polarization states are contemplated as being within the scope of the present invention. Such embodiments include a grating structure including a plurality of single-groove-per-period sub-grating structures, where each sub-grating structure is associated with grating parameters (including wire compositions, substrate material, periodicity, groove width, groove dielectric, period, wire height and shape, and so on), wherein at least one sub-grating structure differs sufficiently from another sub-grating structure to produce enhanced transmission without substantial phase interactions occurring between their associated CMs.

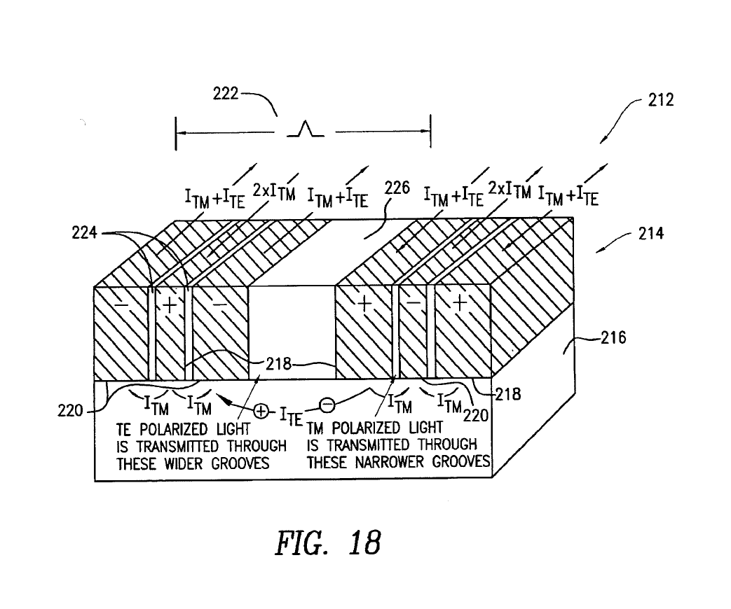

Referring to FIG. 18, in one embodiment of a device formed in accordance with the present invention, a metal-semiconductor-metal photodetector (MSM-PD) 212 that measures an incident beam's intensity and polarization state at a predetermined wavelength includes a multiple-groove-per period grating structure of the present invention. The MSM-PD 212 includes a grating structure 214 fabricated on top of an absorbing semiconductor substrate 216. The device 212 has alternately biased wires, positively biased 218 interspersed between negatively biased wires 220. This structure 214 has three grooves per period 222 with two of the grooves 224 being identical in every regard and selectively transmitting TM-polarized light and one of the grooves 226 selectively transmitting TE-polarized light. The transmitted light generates electron-hole pairs, producing electrical current components Iₚ and Iₛ due to the TM-polarization and TE-polarization components, respectively, of the incident beam. Readout integrated circuitry (ROIC) can then calculate Iₛ given Iₚ and Iₚ+Iₛ. If desired, additional identical TE-polarized light channeling grooves can be inserted to allow for one set of contacts to only collect electron-hole pairs generated by TE-polarized light.

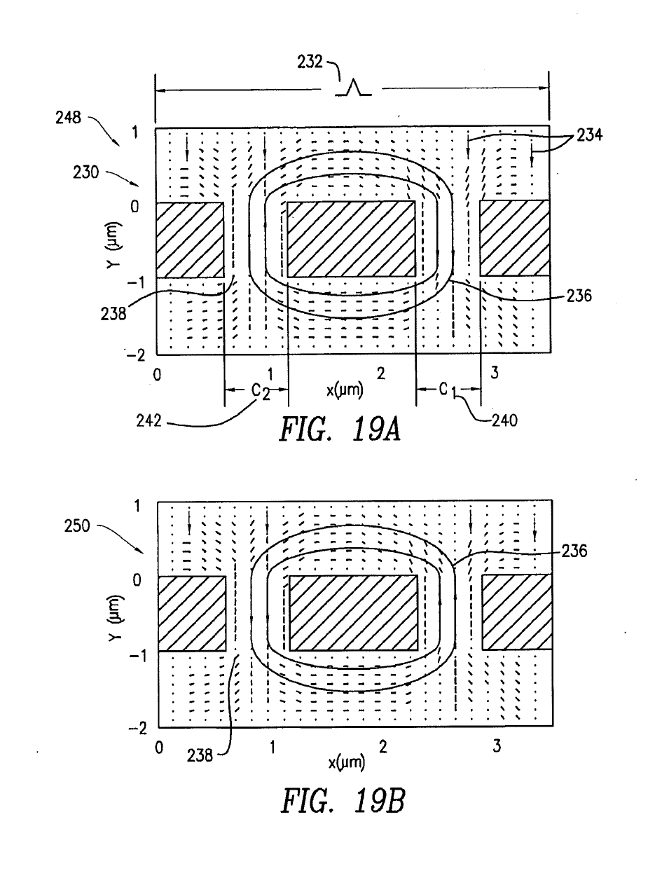

Referring to FIGS. 19A and 19B, another embodiment of the present invention includes a grating structure 230 having multiple-grooves-per-period 232 adapted to support hybrid CMs or “π” modes, which result from so-called phase resonances, that preferentially enhance transmission of a predetermined polarization states at a predetermined wavelength and also produce so-called “light circulation” 234 of the transmitted radiation through the structure 230 as illustrated by the Poynting vector representation in FIGS. 19A and 19B.

In this embodiment, the grating structure includes a plurality of grooves per period. Each groove within the period can be considered to be associated with a sub-grating structure that includes grating parameters (including wire compositions, substrate material, periodicity, groove width, groove dielectric, period, wire height and shape, and so on). At least one sub-grating structure differs sufficiently from another sub-grating structure to produce enhanced transmission and light-circulation, but not enough to prevent phase interactions occurring between their associated CMs.

Though TM-polarized it modes have been reported in the prior art, TE-polarized it modes and the light circulation effect have not. Referring to FIG. 19A, for example, light circulation, as referred to herein, occurs when incident light 234 is transmitted through one set of grooves 236 and then re-transmitted through a second set of preferably differently shaped or composed grooves 238, resulting in a high net reflectivity for the light at a predetermined wavelength, polarization and angle of incidence. Optionally, the same effect can be achieved using an array of holes in a thin (metallic) film.

The light circulating grating structures of the present invention include those that enhance transmission of and produce light-circulation of one or both of TM- and TE-polarized incident light. FIG. 19A shows a Poynting vector representation 248 of the circulating radiation for TE-polarized radiation at a wavelength just below that at which a transmission minimum occurs for the hybrid CMs, and GIG. 19B shows a Poynting vector representation 250 of the circulating radiation for TE-polarized radiation at a wavelength just less than that at which the transmission minimum occurs, causing a shift in the direction of circulation. Further details of these light-circulating modes are provided in Example 3 of the Examples section below.

In Example 3, one embodiment 230 of the grating structure adapted for enhanced transmission and light circulation of TE-polarized light formed in accordance with the present invention has two grooves per period 232, with a first groove width 240 c₁=0.755 microns and a second groove width 242 c₂=0.735 microns, and ∈_{1groove} equaling ∈_{2groove}=23. The wires are gold. This structure is a light-circulating structure for the TE-mode at a normal angle of incidence of the incident light.

In another embodiment of the grating structure described in Example 3, if the groove dielectric are also changed so that ∈_{1groove} does not equal ∈_{2groove} but rather ∈_{1groove}=25 and ∈_{2groove}=21, then enhanced transmission and light circulation of TM-polarized light occurs for light at a normal angle of incidence. Accordingly, the light-circulating grating structures of the present invention can be adapted to produce hybrid CM or π modes for light-circulation of any predetermined polarization state at a predetermined wavelength.

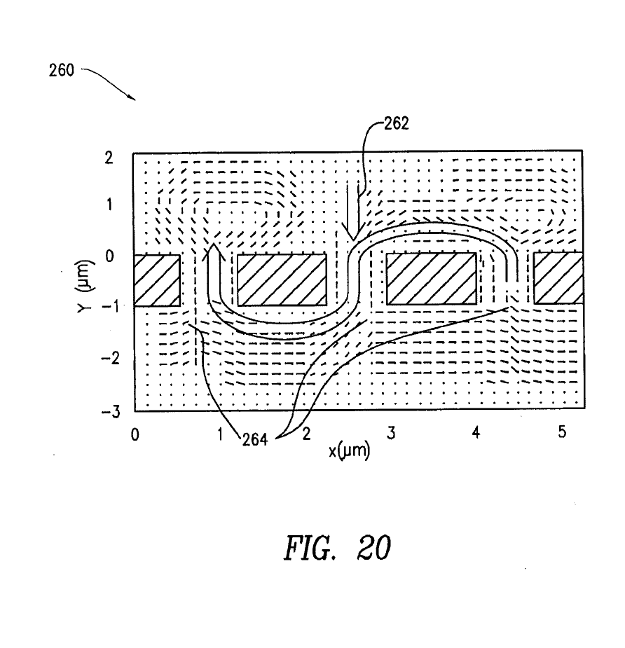

Referring to FIG. 20, any of the light circulating grating structures can be a light weaving structure 260 at non-normal angles of incidence.

“Light weaving” occurs when incident electromagnetic radiation 262 with a nonzero in-plane momentum (i.e., momentum in the direction parallel to the surface of the wire) is woven through alternating grooves 264, localizing light near the wires as it travels parallel to them. The light weaving grating structures of the present invention can be useful for photodetectors or for the propagation of signals or data.

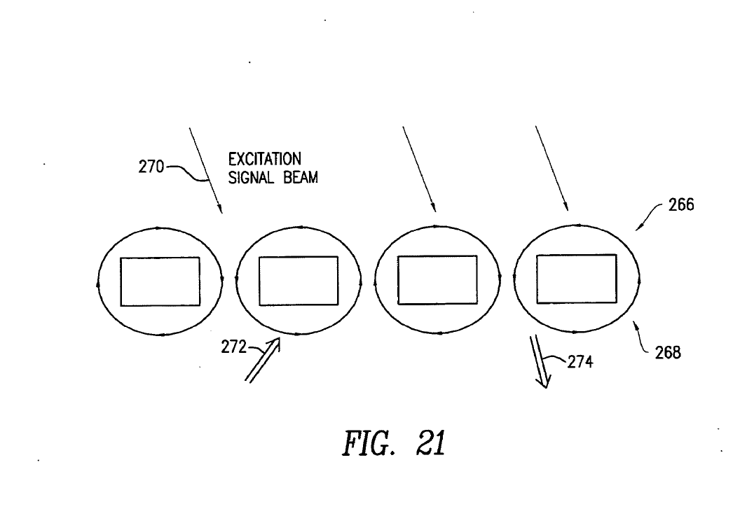

Referring to FIG. 21, in one embodiment, a device including a light-circulating grating structure 266 of the present invention is adapted for use with an incident pulsed light signal 270 that is short in time duration, i.e., a transient pulse, including ultrafast pulses and pulses with time durations on the order of less than a femtosecond to a microsecond, so that the light circulation modes 268 cause light to be continually circulated around the wires in the grating through grooves, which are optionally holes in a preferably metal film. Light circulation will continue even after the excitation beam 270 is extinguished. The circulating light can then the released from the grating structure 266 by a probe beam 272 from either the top or the bottom resulting in the controllable “stopping” and “releasing” of an emitted signal beam 274 that will radiate away from the structure 266 with a portion of the probe beam that is reflected. The grating structure 266 can be adapted for use in a light storage, or memory, or controlling device structure.

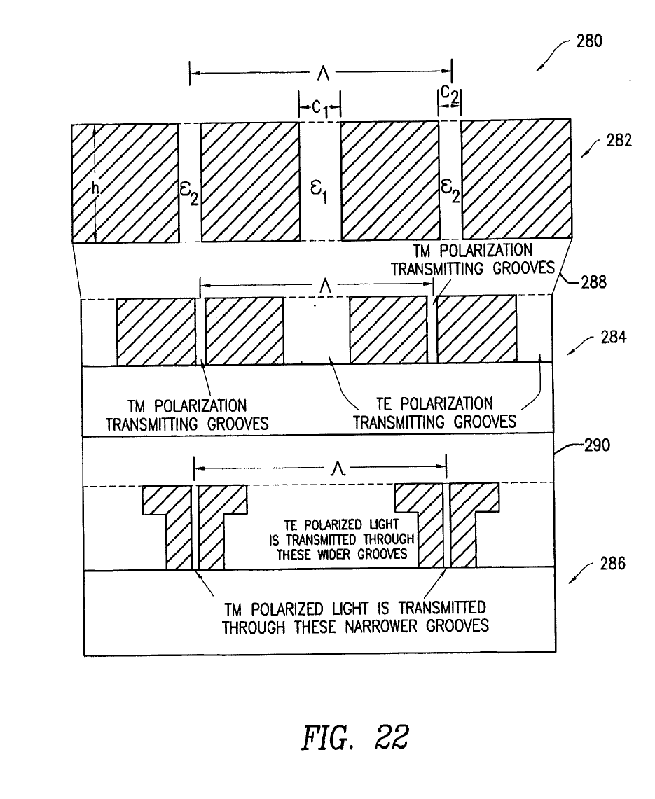

In yet another embodiment of the grating structure shown in FIG. 22 of the present invention, any combination of layers 282, 284, 286, for example, of any of the grating structures of the present invention, with or without substrates, can be combined and separated by spacer layers 288 and 290, e.g., to produce the desired light circulating modes.

Hole arrays in thin, preferably metal, films that are adapted and arranged to produce the light circulating modes described herein are also considered within the scope of this invention.

### Methods

One embodiment of a method for tailoring any of the PETS grating structures of the present invention includes applying a coupled mode algorithm that uses the well-known surface impedance boundary conditions (SIBC) as described in Example 1 provided below in the “Examples” section.

Example 1 assumes normal incident radiation, but the grating structures of the present invention also include those optimized for enhanced transmission at any predetermined angle of incidence, depending on the particular application and desired result.

Various parameters, including wire compositions, refractive index of a groove material, substrate material, periodicity, groove width and height can be varied, as described in Example 1, to optimize parameters for the grating structure having enhanced transmission of the desired polarization state(s) at the desired predetermined wavelength and for a predetermined bandwidth.

The present invention, therefore, includes a method of optimizing the spacing between the wires, pitch, and orientation to exploit the optical and surface plasmon resonances effect, to achieve polarization independent enhanced optical transmission. These parameters can be optimized in accordance with the preferred wavelength, polarization, and angle of incidence in accordance with the present invention. The height defined by the metal wires can be further optimized to achieve different line widths for the transmission peaks.

In particular, one embodiment of the method of the present invention assumes, as an approximation, that the CMs are perfectly confined to the grooves. For CMs perfectly confined to the grooves, their wavelengths are given by Equation (3):

$$\frac{2 π}{{λ}_{peak}} = {n}_{groove} \sqrt{{( \frac{π n}{h} )}^{2} + {( \frac{π m}{c} )}^{2}} \qquad ( 3 )$$

where n and in are integers and n_{groove}(=\sqrt{∈_{groove}}) is the index of refraction of the dielectric material 88 in the grooves 74.

Even though CMs are not perfectly confined to the grooves, Equation (3) is still approximately true for CMs produced by waveguide modes and even for CMs produced by TM-polarized VSPs. More importantly, inherent in Equation (3) are the dependencies of the CMs on the structural parameters n_{groove}, h, and c of the grating structures of the present invention, with the lowest in value allowable for TM-polarization (also referred to as “p-polarization”) and TE-polarization (also referred to as “s-polarization”) being m=0 and n=1 respectively. Because of this last fact, the lowest order TE-polarized CM occurs at a higher energy than the lowest energy p-polarized CM. Depending on the ratio of h/c, there can be many TM-polarized CMs with lower energies than the lowest energy TE-polarized CM, resulting in an undesirably large wavelength separation between the lowest order CMs for the different polarizations.

A more thorough description of all the dependencies of the TE-polarized and TM-polarized CMs on structural parameters (e.g., groove width, height and groove dielectric constant) is given in Crouse 2007, and also in Example 1 in the Examples section below.

Summarizing these dependencies, the TM-polarized CMs have strong dependencies on h and ∈_{groove} and a weak dependence on c if the m=0 mode is used. Also, TM-polarized CMs can have a strong dependence on Λ, especially when Λ is such to produce a Wood-Rayleigh anomaly (WR) or a HSP at a wavelength close in value to that of the CM. The TE-polarized CMs have strong dependencies on h, c, and ∈_{groove} and a weak dependence on Λ. With these basic characteristics and structural dependencies of the CMs in mind, one embodiment of a method for tuning (with respect to wavelength) the lower order TE-polarized CMs and TM-polarized CMs is provided as follows.

The method and gratings of the present invention allow for the use of a high-index (or high-k) dielectric material in the grooves, which has the following advantages. To achieve the highest degree of transmission of an incident beam of radiation into the 0^{th} order (“straight-through”) transmitted beam, the transmission enhancing CMs for both TM and TE polarizations should occur at a lower energy than the onset of 1^{st} order diffraction. For the grating structure of the present invention superposed on a substrate (e.g., glass, semiconductors, and so on) with a dielectric constant of n_{substrate}=(\sqrt{∈_{substrate}}), the onset of 1^{st} order diffraction occurs for a wavelength λ_{1st order}=Λ/n_{subsrate}. For substrates other than air, realistic aspect ratios (height/width of the grooves), and with h small enough to produce TM-polarized CM transmission peaks that do not crowd together (i.e., the bandwidth of the transmission peaks is at least twice the wavelength separation of adjacent peaks), a material within the grooves with a dielectric constant at least as large as the substrate's is typically desirable to lower the energy of the TE-polarized CMs below the onset of 1^{st} order diffraction. Also, high-index dielectrics (e.g., high-k dielectrics, such as hafnium oxide or ditantalum pentoxide) inhibit TM-polarization transmission through the relatively wide TE-polarization transmitting grooves (relative to the width of TM-polarization transmitting grooves) when a TM-polarized CM is not excited.

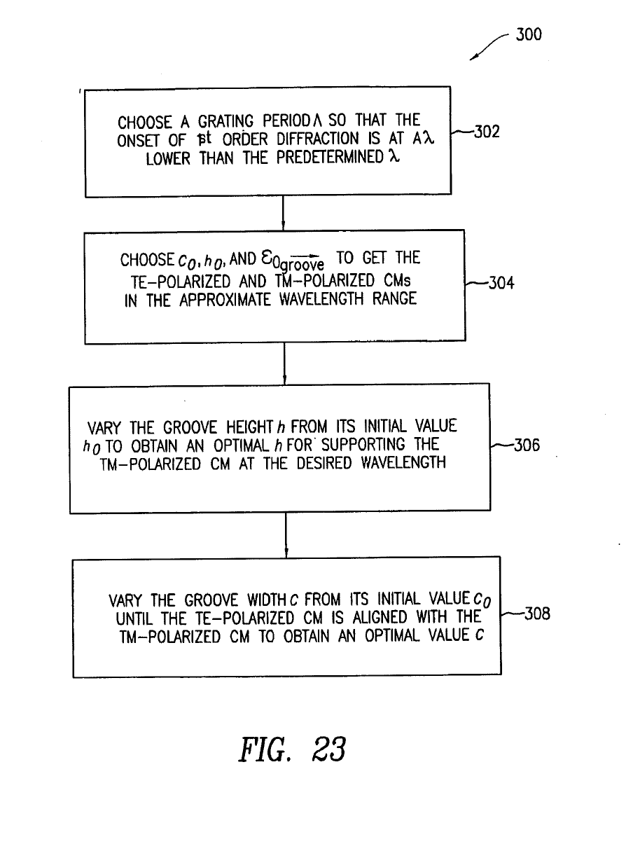

Accordingly, with reference to FIG. 23, one embodiment 300 of the method of the present invention for tuning and aligning the CM-produced enhanced transmission peaks for TE-polarized and TM-polarized light incident on grating structures with only one groove per period includes the following series of steps:
1. Choose 302 a grating period Λ so that the onset of 1 order diffraction is at a lower wavelength than the predetermined wavelength at which enhanced transmission is desired; the grating period Λ is also chosen to be less than the predetermined wavelength.
2. Choose 304 an initial value for c, h, and ∈_{groove} to get the TE-polarized and TM-polarized CMs in the approximate wavelength range desired, using the following relationships, as discussed above. The larger h is, the closer spaced (in wavelength) the CMs are for each polarization. The larger the aspect ratio h/c is, the higher the Q-factor the CMs. Too large of an aspect ratio, however, will produce large absorption for real metals. Importantly, grooves that are wide enough to support a TE-polarized CM will generally allow TM-polarized light to be transmitted in appreciable amounts even when a TM-polarized CM is not excited. One way around this problem is to use a high-index dielectric that does two things: (1) increases the effective width and height of the groove by a factor of \sqrt{∈_{groove}} and (2) increases the impedance for TM-polarized light, thereby reducing the TM-polarization transmission when a TM-polarized CM is not excited.
3. Vary 306 the groove height h from its initial value to obtain an optimal groove height h for supporting the TM-polarized CM at the desired wavelength.
4. Vary 308 the groove width c from its initial value until the TE-polarized CM is aligned with the TM-polarized CM to obtain an optimal value of groove width c. The alignment may be performed, e.g., by plotting the peak TE and peak TM as a function of wavelength and groove width, e.g., as shown in FIG. 7.

An example of a grating structure formed according to this method is provided as Example 2 in the Examples section below.

The optimized parameters determined in accordance with any of the methods of the present invention can be used to fabricate any of the grating structures of the present invention using any appropriate method of fabrication known to those of ordinary skill in the art for fabricating sub-wavelength gratings.

For example, for the grating structures optimized to enhance radiation at predetermined wavelengths in the ultraviolet, visible and near infrared, mid-infrared long wavelength infrared and very long wavelength infrared, standard microfabrication technologies can be used. Such fabrication methods can include physical deposition of the wires and groove and substrate materials such as metals, oxides and semiconductors by thermal evaporation, electron beam evaporation, sputtering, or chemical vapor deposition.

The grating structures of the present invention can be generated using photolithography or electron beam lithography along with wet chemical etching and/or reactive on etching or ion beam milling. For structures that operate in wavelength regions longer than the very long wavelength infrared, such as the terahertz and microwave regions, less expensive fabrication techniques can be used, including computer numerical control (CNC) micro milling; machines.

### EXAMPLES

### Example 1

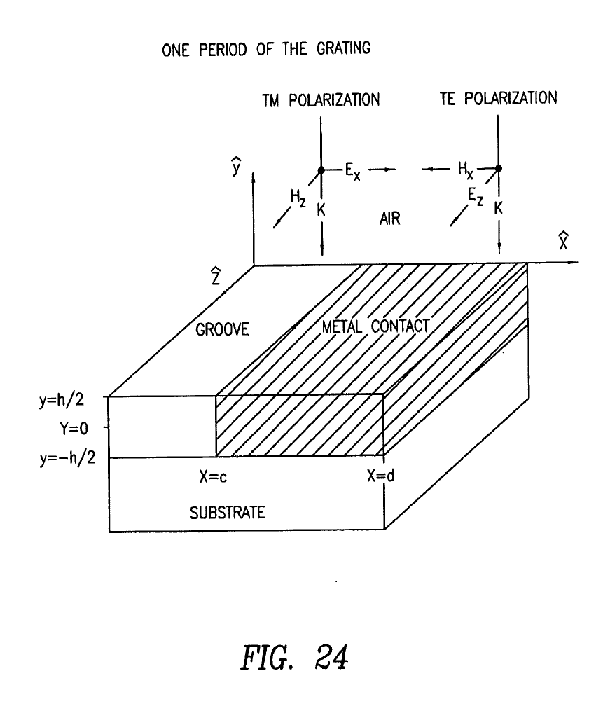

The optical and electromagnetic characteristics of lamellar gratings, such as those of the present invention, are modeled in this example using a coupled mode algorithm that uses the surface impedance boundary condition (SIBC) approximation. This method is described in detail in D. Crouse, “Numerical Modeling and Electromagnetic Resonant Modes in Complex Grating Structures and Optoelectronic Device Applications,” IEEE Trans. Electron Devices 52: 2365-2373 (2005), the entirety of which is incorporated herein by reference, and are only summarized here. Referring to FIG. 24, this method uses the following approximation relating the tangential components of the electric and magnetic fields at a dielectric/metal interface:

E_{II}=Z\hat{n}×H_{II} (A1)

where Z=1/nₘₑₜₐₗ, with nₘₑₜₐₗ being the complex index of refraction of the metal. This approximation is valid if the dielectric constant of the metal is much larger than the neighboring dielectric (which is largely true in the infrared and visible spectral regions).

FIG. 24 defines the coordinate system used in the calculation. Only one period of the grating is shown. In the calculations, the top layer is assumed to be air.

The electromagnetic fields are expressed as a linear combination of orthogonal modes as follows:

$$\begin{matrix}\text{?} ( x , y ) = exp ( i ( {α}_{n} x - {β}_{n} ( y - h .2 ) ) ) + {\sum }_{n = - ∞}^{∞} {R}_{n} exp ( i ( {α}_{n} x + {β}_{n} ( y - h / 2 ) ) ) & ( A2 ) \\ {f}_{groove} ( x , y ) = \text{?} ( x , y ) & ( A3 ) \\ {f}_{substrate} ( x , y ) = {\sum }_{n = - ∞}^{∞} {T}_{n} exp ( i ( {α}_{n} x - {\tilde{β}}_{n} ( y + h / 2 ) ) \\ \text{?} \text{indicates text missing or illegible when filed} & ( A4 )\end{matrix}$$

where f₁(x, y) is the \hat{z} component of the magnetic field or the \hat{z} component of the electric field depending on if the TM polarization or TE polarization is being modeled respectively. The other electric and magnetic field components can be obtained using relations derived from Maxwell's equations. Also, αₙ=kₒ sin θ_{incident}+nK, K=2π/d, βₙ=\sqrt{kₙ²−αₙ²}, \tilde{β}ₙ\sqrt{∈_{substrate}kₒ²−αₙ²} with n is an integer, d being the period of the structure θ_{incident} the angle of incidence, λ the wavelength, and ∈ᵢ the dielectric constant of the i^{th} region. In Eqs. (A1) and (A3), the orthogonal modes used in the modal expansion are plane waves in the air and substrate layers and the following orthogonal modes Φₙ (x, y) are used in the grooves:

Φₙ(x,y)=Xₙ(x)Yₙ(y) (A5)

Xₙ(x)=d sin(μₙx)+cos(μₙx) (A6)

Yₙ(y)=aₙexp(iξₙy)+bₙexp(−iξₙy) (A7)

where the terms μₙ and ξₙ obey the relation:

μₙ²+ξₙ²=∈_{groove}kₒ² (A8)

Applying the SIBC condition to the left-hand and right hand sides of the grooves results in the following equations (respectively):

$$\begin{matrix}{d}_{n} = \frac{{η}_{groove}}{{μ}_{n}} & ( A9 ) \\ tan ( c {μ}_{n} ) = \frac{2 {η}_{groove} {μ}_{n}}{{μ}_{n}^{2} - {η}_{2}^{2}} & ( A10 )\end{matrix}$$

where c is the width of the groove and η_{groove}=kₙ∈_{groove}Z/i for TM polarization and η_{groove}=kₐ/iZ for TE polarization. The most essential step in the above method is the solution to Eqn. (A10). In this method the roots of Eqn. (A10) are found by integration starting from an initial value. We have performed the integration using the Runge-Kutta method.

Applying boundary conditions equating the tangential field components and the SIBC conditions at the metal/dielectric interfaces at y=h/2 and y=−h/2 yields the following equations.

$$\begin{matrix}{\sum }_{n = - ∞}^{∞} ( {I}_{n} + {R}_{n} ) {e}^{{iα}_{n} x} = {\sum }_{m}^{∞} {X}_{m} ( x ) ( {ϕ}_{m} {a}_{m} + {ϕ}_{m}^{- 1} {b}_{m} ) 0 \leq x \leq c & ( A11 ) \\ i \text{?} {β}_{n} ( - {I}_{n} + {R}_{n} ) {e}^{{iα}_{n} x} = \{ \begin{matrix}i \frac{\text{?}}{\text{?}} \text{?} X ( x ) \text{?} ( {ϕ}_{m} {a}_{m} - {ϕ}_{m}^{- 1} {b}_{m} ) & 0 \leq x \leq c \\ \text{?} ( {I}_{n} + {R}_{n} ) {e}^{{iα}_{n} x} & c \leq x \leq d\end{matrix} & ( A12 ) \\ {\sum }_{n = - ∞}^{∞} {T}_{qn} {e}^{{iα}_{n} x} = {\sum }_{m}^{∞} X ( x ) ( {ϕ}_{m}^{- 1} {a}_{m} + {ϕ}_{m} {b}_{m} ) 0 \leq x \leq c & ( A13 ) \\ i \text{?} {e}^{{iα}_{n} x} = \{ \begin{matrix}- i \frac{{γ}_{substrate}}{{γ}_{groove}} {\sum }_{m}^{∞} {X}_{m} ( x ) \text{?} ( {ϕ}_{m}^{- 1} {a}_{m} - {ϕ}_{m} {b}_{m} ) & 0 \leq x \leq c \\ {η}_{substrate} {\sum }_{n = - ∞}^{∞} {T}_{n} \text{?} & c \leq x \leq d\end{matrix} \\ \text{?} \text{indicates text missing or illegible when filed} & ( A14 )\end{matrix}$$

where

$${γ}_{air} = {ɛ}_{air} = 1 , \\ \text{?} = \text{?} , \\ {γ}_{substrate} = {ɛ}_{substrate} , \\ {η}_{air} = {k}_{n} Z / i$$

$$and$$

$${η}_{sub strate} = {k}_{a} {ɛ}_{substrate} Z / i$$

$$\text{?} \text{indicates text missing or illegible when filed}$$

for the TM polarization and

$${γ}_{air} = \text{?} = {γ}_{substrate} = 1 , \\ {η}_{air} = {η}_{substrate} = {k}_{n} / iZ$$

$$\text{?} \text{indicates text missing or illegible when filed}$$

for the TE polarization and

$$\text{?} = \text{?} . \\ \text{?} \text{indicates text missing or illegible when filed}$$

Then multiplying Eqs. (A11) and (A13) by Xᵢₙ (x) and integrating over the region 0≦x≦c and multiplying Eqs. (A12) and (A14) by

$${e}^{i {α}_{η} x} / d$$

and integrating over the region 0≦x≦d yields the following matrix equations that are used to determine the unknown coefficients Rₙ, Tₙ, aₙ and bₙ:

$$\begin{matrix} M Ψ = Ω \\ with & ( A15 ) \\ M = ( \begin{matrix}G & - N ϕ & - N {ϕ}^{- 1} & 0 \\ i β - \text{?} J & - i \frac{\text{?}}{{γ}_{groove}} K \text{?} ϕ & i \frac{\text{?}}{{γ}_{groove}} K \text{?} {ϕ}^{- 1} & 0 \\ 0 & - N {ϕ}^{- 1} & - N ϕ & G \\ 0 & - i \frac{{γ}_{substrate}}{{γ}_{groove}} K \text{?} {ϕ}^{- 1} & i \frac{{γ}_{substrate}}{{γ}_{groove}} K \text{?} ϕ & i \tilde{β} + {η}_{substrate} J\end{matrix} ) & ( A16 ) \\ Ψ = ( \begin{matrix}R \\ a \\ b \\ T\end{matrix} ) \\ and \\ Ω = ( \begin{matrix}- GI \\ ( iβ + \text{?} J ) I \\ 0 \\ 0\end{matrix} ) \\ \text{?} \text{indicates text missing or illegible when filed} & ( A17 \text{-} A18 )\end{matrix}$$

where the matrices φ, β, ξ are square matrices with nonzero components along the main diagonal given by φ [symbol] , βₙ, ξ [symbol] , that have been previously defined; G, K are matrices with components given by:

$$\begin{matrix} {G}_{mn} = {\int }_{0}^{c} {X}_{m} ( x ) exp ( {iα}_{n} x ) d x & ( A19 ) \\ {K}_{nm} = \frac{1}{d} {\int }_{0}^{c} {X}_{m} ( x ) exp ( - {iα}_{n} x ) d x & ( A20 ) \\ {J}_{qn} = \frac{1}{d} \text{?} exp ( i ( {α}_{n} - {α}_{q} ) x ) d x & ( A21 ) \\ \begin{matrix}{N}_{mn} = {\int }_{0}^{c} {X}_{m} ( x ) {X}_{n} ( x ) d x \\ = {δ}_{mn} [ ( {( \frac{{η}_{groove}}{{μ}_{m}} )}^{2} + 1 ) \frac{c}{2} + \frac{{η}_{groove}}{{μ}_{m}^{2}} ]\end{matrix} \\ \text{?} \text{indicates text missing or illegible when filed} & ( A22 )\end{matrix}$$

The number of modes used in the electromagnetic field expansions were large and the solutions were convergent. The results obtained using the above approach were checked using another method that assumes that the walls of the grooves are perfectly conducting. These results yield practically identical results indicating that even though the convergence of TE polarization solutions using the SIBC approximation is worse than the convergence of TM polarization solutions, the main results showing EOT for both TM and TE polarizations will hold true when more accurate methods are used for the calculations.

Once Eq. (A15) is used to find all of the unknown coefficients, the reflectance (i=air in Eq. A23), transmittance and diffraction efficiencies (i=substrate in Eq. A23) can be calculated as the ratio of the ŷ-component of the Poynting vector for an outward propagating mode and the ŷ-component of the incident beam (assuming a normalized incident beam and a top layer being air):

$$\vert \frac{{S}_{y , n}}{{S}_{y , incident}} \vert = \frac{\sqrt{{ɛ}_{i}}}{{γ}_{i}} \frac{cos {θ}_{outward , n}}{cos {θ}_{incident}} {\vert \text{?} \vert}^{2} \\ \text{?} \text{indicates text missing or illegible when filed} \qquad ( A23 )$$

where Ω [symbol] is either Rₙ or Tₙ and θ [symbol] is the angle of the outward propagating mode.

### Example 2

Referring to FIG. 5C and FIG. 6, an embodiment of the single-groove-per-period grating structure 58 was fabricated for enhanced transmission of both TE-polarized and TM-polarized microwaves at a predetermined frequency of 25.188 GHz (wavelength λ=11.91 min). The grating structure has AI contacts or wires (∈_{AI}+−10⁴+i·10⁷), a period of 10.3428 mm, groove width of 3.8211 mm, thickness of 6.045 mm, groove dielectric constant of 2.8, and air for the substrate and superstrate. The experimental results for this simple grating structure verified the accuracy of the numerical modeling algorithms provided herein and the concepts of CM-induced enhanced transmission, thereby allowing for these algorithms and concepts to also be used in the design of more complex grating structures having more than one groove per period, as shown, for example, in FIG. 22.

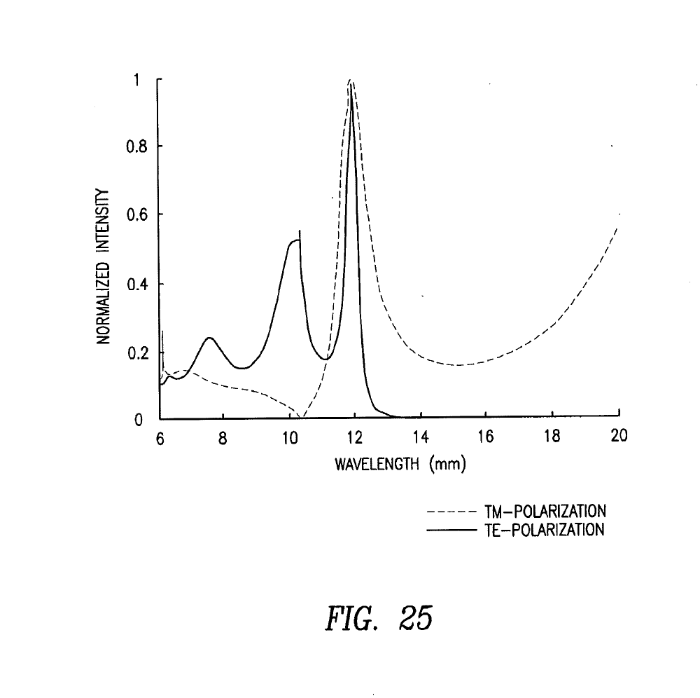

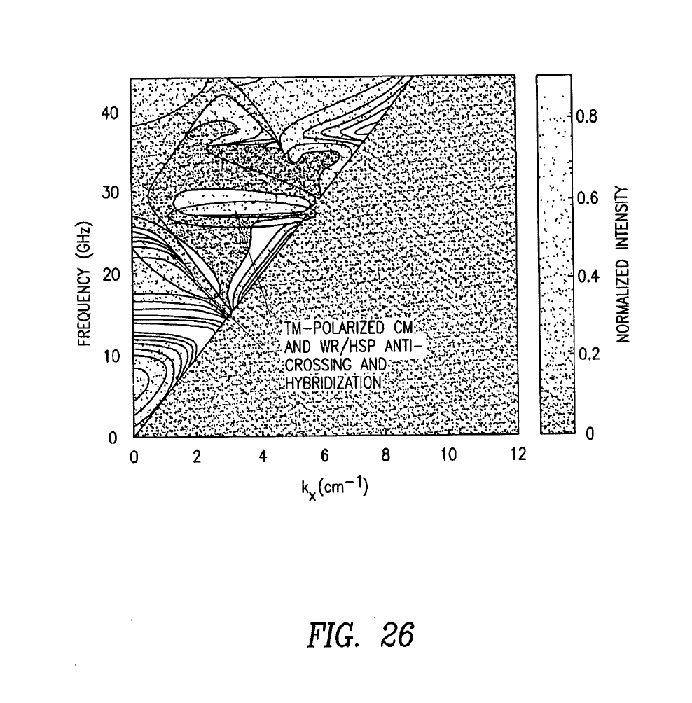

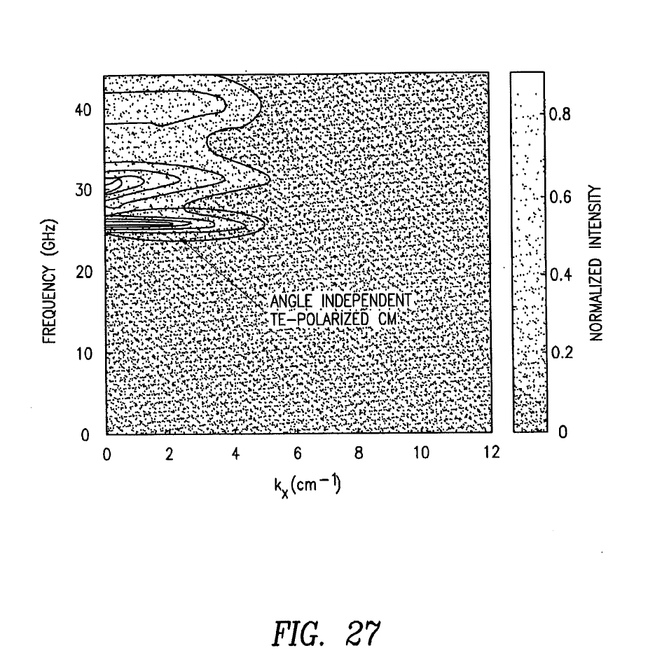

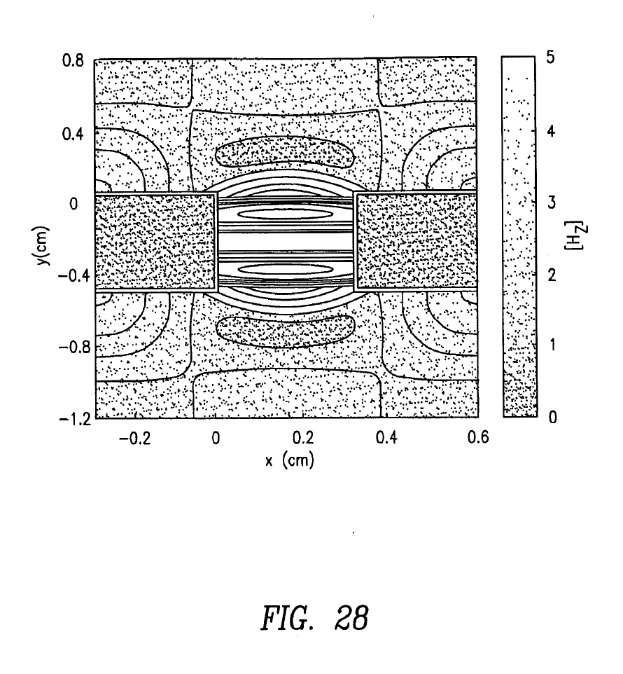

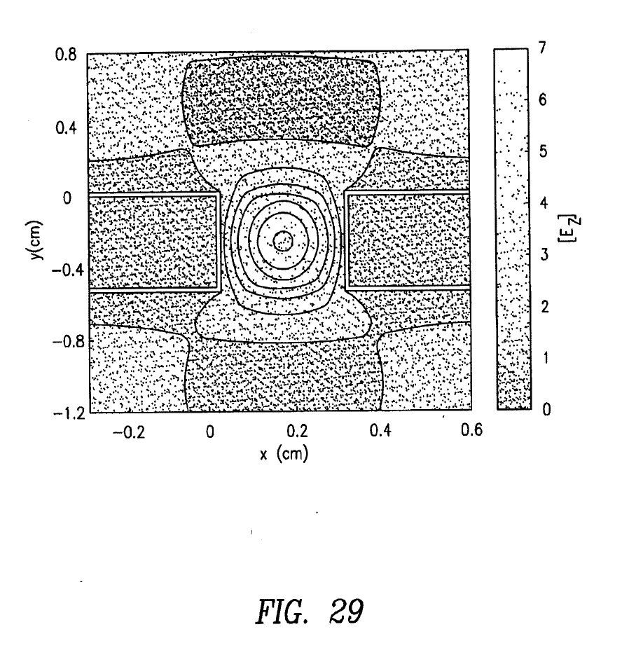

Two numerical modeling methods were used and their results compared to ensure agreement and accuracy. One method uses the surface impedance boundary condition (SIBC) approximation and allows for very quick calculation of all optical characteristics of a wide range of grating structures. The other method is the finite-element method solver HFSS™ commercially available from Ansoft Corp. Note that CMs, HSPS, VSPs, WRs, diffraction and all other optical effects occur in the microwave as they do in the infrared (IR) and visible spectral regions but the CMs and diffraction features occur at wavelengths that scale with groove height and width and grating pitch or period. The transmittance (FIG. 25), the full ω-k reflectance and transmittance profiles (FIGS. 26-29), and the magnetic field and electric field intensities of the 25.188 GHz TM-polarized and TE-polarized CMs respectively were obtained using the SIBC algorithm. The normal incidence transmittance and reflectance were also obtained using HFSS™ (results of which are not shown for the sake of clarity and brevity) and agreed with the SIBC results. Properties of the TM-polarized and TE-polarized CMs are also discussed in Grouse 2005 and Grouse 2007 and can be seen in these FIGS. 26-29, including the high transmittance, the small angle of incidence dependence, and the interaction and anti-crossing of TM-polarized CMs and WRs.

The fabricated device was formed in accordance with the methods presented herein to produce cavity modes that simultaneously couple to TM- and TE-polarized radiation at the predetermined wavelength of 11.91 mm. Such millimeter-scale structures are far cheaper and quicker to fabricate than their nanoscale counterparts, and they can provide just-as-good experimental verification of the pertinent theoretical constructs, since the effects and wavelengths of the WRs and CM modes responsible for the device performance all scale with the device dimensions. In the case of periodic features on a millimeter scale, for example, theory predicts that enhanced transmission will be observed in the microwave spectral region. In moving from the IR to microwave spectral region, the only difference between the reflectivity and transmittance curves is the slightly higher energies and intensities for the HSP and CM resonances, as metals in the microwave behave as almost perfect conductors; the dielectric constant of A1 that is used is ∈_{A1}=10⁴+i·10⁷ for the microwave to λ=31 μm and tabulated data²⁶ from λ=31 μm to λ=600 nm. Additionally, unlike studies undertaken in the visible or even the IR, we need not worry about variation in the permittivity of the materials used; essentially the metal is perfectly conducting, and the dielectric filling the grooves is virtually non-dispersive at these wavelengths. It is therefore a very sensible approach to undertake these proof-of-principle studies at longer wavelengths.

The experimental sample was constructed by machining a set of identical grooves, each or width c=3.82 mm, spaced with a periodicity of Λ=10.34 mm and milled all the way through an aluminum alloy plate of thickness h=6.05 mm to cover an area of approximately 400 mm×400 mm. The voids were then carefully filled with an elastomer (Dow Corning® Sylgard® 184 silicone encapsulant) that had been mixed and left to rest under vacuum until completely evacuated. The real part of the permittivity of the elastomer is ˜2.8 in the GHz regime. Linearly polarized microwave radiation from a standard gain horn was collimated using a spherical mirror to impinge upon the sample at normal incidence. A continuous wave source sweeps the frequency in bands 18≦v≦26.5 GHz and 26.5≦v≦40 GHz (i.e., 7.5≦λ≦16.7 mm) and feeds the fixed position antenna. Before striking the sample, the incident beam was passed through an aperture of a broadband microwave absorbing material in order to restrict the incident beam spot to the useful sample area. Furthermore, in order to obtain averaging of the transmitted signal over a large number of grating periods, the transmitted beam is collected using another spherical mirror before being focused into a second horn antenna and detector. The polarization of both the incident beam and that detected can be altered in this configuration via simple rotation of each horn antennae about its central axis.

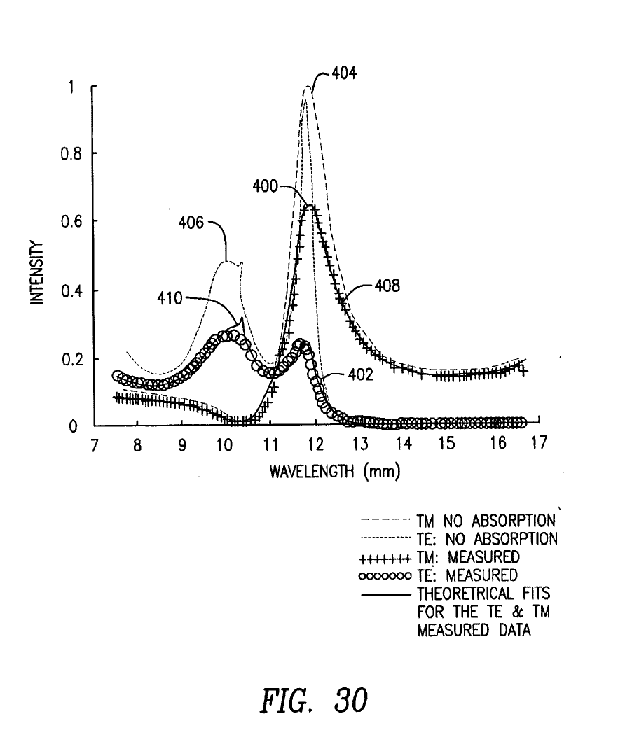

The experimental transmissivity data, setting both the incident and detected polarizations to either TM-polarization 400 or TE-polarization 402, normalized to a spectrum in the absence of the sample, are shown in FIG. 30 (+ and ⊚ respectively). As is seen in FIG. 30, the experimental transmittivities are substantially reduced relative to the predicted values 404 and 406 respectively obtained by numerical modeling, however once a small absorptive component, associated with a Debye dielectric response of the polymer and impurities, is included in the dielectric constant of the elastomer used in the modeling, the modeled 408 and 410 respectively and experimental curves 400 and 402 match very well. Hence, by fitting the experimental data to the modeling, it was found that the structure that was fabricated had a groove width of 3.824 mm and a dielectric constant for the groove of ∈_{groove}=2.75+i·0.0945. The magnitude of these dielectric losses can be reduced by the use of crystalline powders instead.

### Example 3

It is known that phase resonances for TM-polarized incident light can arise in gratings that have multiple grooves per period that differ with respect to composition, geometry or orientation. In these types of structures, TM-polarized VSP-CMs in neighboring grooves can couple, producing field profiles of equal magnitude but with a π radians phase difference; such modes have come to be called it modes or resonances, as described, for example, in Alastair P. Hibbins, et al., Physics Review Letters 96 257402 (2006). However, light-circulation has not been previously reported for any polarization.

For TE-polarized light, there is no component of the electric field that is normal to any metal/dielectric interface, and hence SPs and VSP-CMs cannot be excited, However, Applicants have found that WG-CMs do occur, and along with Rayleigh anomalies, are responsible for a large number of the enhanced or anomalous optical effects, including TE-polarized π modes with properties similar to the properties of TM-polarized π modes. The light circulation and weaving effects of the multiple-groove-per-grating structures formed in accordance with the present invention have been found by Applicants to occur for both s-polarized and p-polarized incident light.

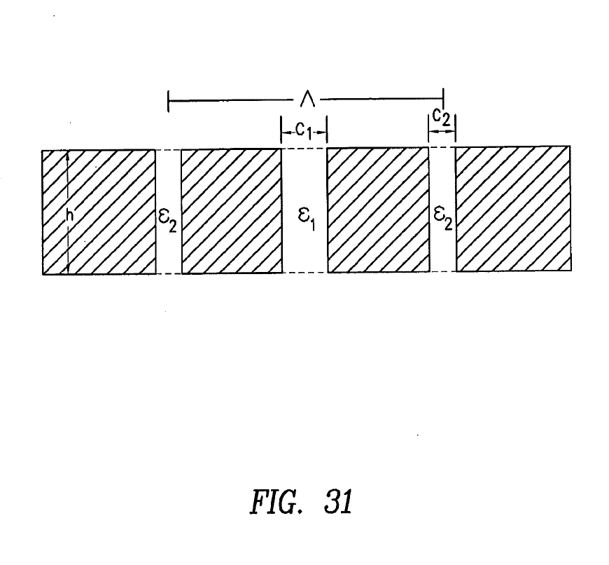

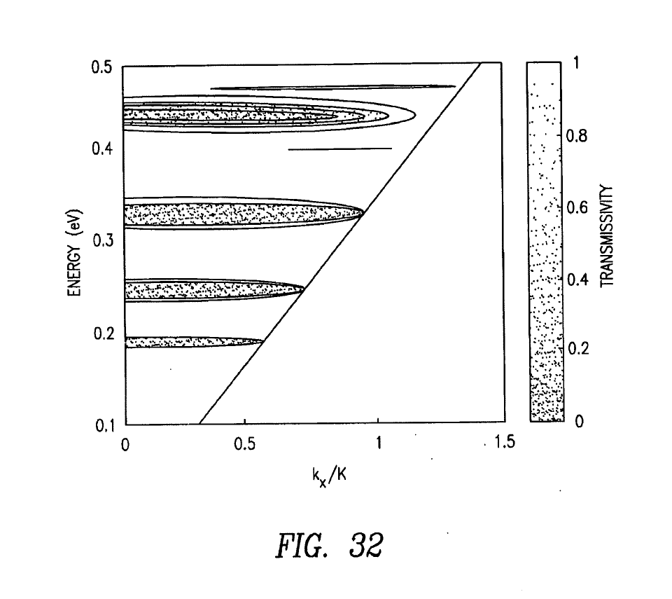

To demonstrate a grating structure adapted to support hybrid CMs for inducing light circulation in accordance with the present invention, two grating structures are discussed in reference to FIG. 31. These two grating structures exhibit many anomalous optical characteristics for both TM-polarized (also referred to herein as p-polarized) and TE-polarized (also referred to herein as s-polarized) incident light. The first grating, denoted as Grating 1, has identical grooves with widths c=0.745 μm, height h=1 μm, dielectric ∈=23, period Λ=1.75 μm, gold for the wires and air as the superstrate and substrate. As is shown in FIG. 32, this structure exhibits a number of WG-CM bands that produce s-polarization enhanced transmission (this structure also exhibits p-polarization enhanced transmission (not shown)).

If the widths of the grooves are perturbed so that every other groove has a width of c₁=0.755 μm and the rest of the grooves have widths of c₂=0.735 μm while keeping all the other parameters unchanged, the resulting structure is the two-groove-per period Grating 2 of FIG. 31. The band folding techniques described, e.g., in Crouse 2005 can be used to construct the approximate shapes of the resulting photonic and plasmonic bands. For s-polarization, such band folding is not necessary because the WG-CM bands are satisfactorily explained by the fact that the two WG-CMs in the two dissimilar, neighboring grooves have slightly different resonant frequencies, causing each of the original bands in the single-groove-per-period grating to split into two bands that interact with each other.

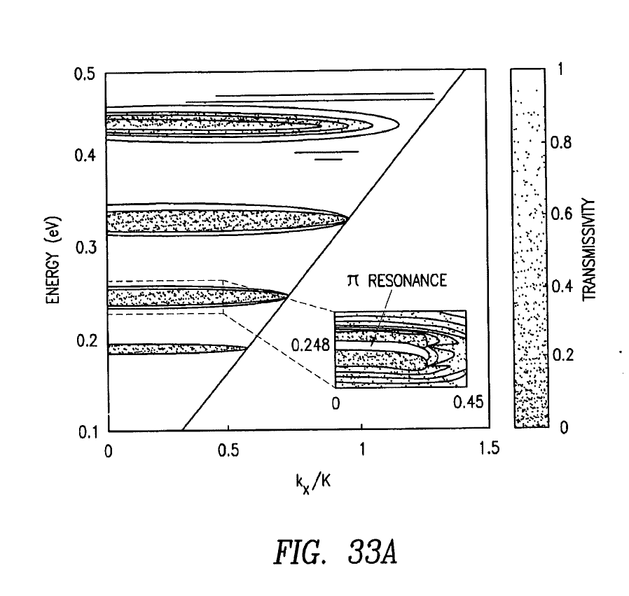

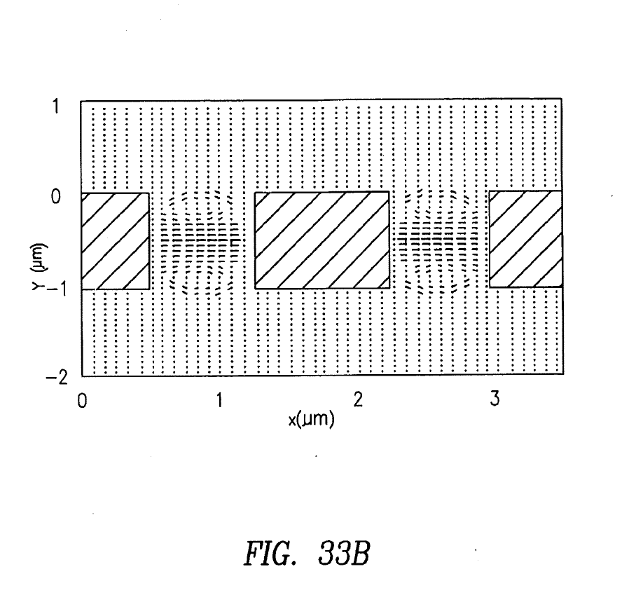

FIG. 33A shows the full ω-k diagram showing that the s-polarized WG-CMs are more complex than the WG-CMs shown in FIG. 32 for the single-groove-per-grating structure, with every CM band split into two CM bands that are separated by an s-polarized π mode producing a transmission minimum at an energy of 0.24815 eV. Also, additional diffraction modes and CM/diffraction interactions are produced.

Many similarities and several important differences between s-polarized and p-polarized π modes exist. The Poynting vector representation of FIG. 33B shows an s-polarized π mode with a π radian difference in the phase of H in neighboring grooves that is similar to the π radian difference in the phase of E in neighboring grooves for p-polarized π modes. However, the dispersions of all the s-polarization bands are far less than the dispersion of p-polarized photonic bands. Another important difference is that s-polarized it modes are necessarily produced by coupled WG-CMs because of the absence of SPs.

The incident beam cannot directly couple to the π radian out-of-phase field in every other groove. Because of this fact, the it resonances will always be located on the shoulders of the broad transmission peak. Applicants have observed in numerous two-groove-per-period gratings that the s-polarized π modes tend to be closer to the center of the transmission peak than the p-polarized π modes. This property arises because of the different components that make up the s-polarized and p-polarized π modes. Applicants have found that the components of the s-polarized π mode are two very similar, inherently radiative, WG-CMs that have slightly different resonant frequencies. The alternating groove width perturbation simply splits the original WG-CM band into two bands that are slightly asymmetric bands because the it resonance still has to occur on the shoulder of the original WG-CM transmission peak, but typically more symmetric than the two transmission peaks one either side of a p-polarization π mode. This greater symmetry affects the light circulation produced by π mode.

By examining the power flow, Applicants found that at or around the transmission minimum produced by the π modes, light is transmitted with high transmissivity through the two sets of grooves but then circles around, and is transmitted with high transmissivity through the neighboring grooves, resulting in a reflection maximum. It is clear that π modes are hybrid modes, composed of two coupled s-polarized WG-CMs. Furthermore, at the transmission minimum, these two transmission channels, created by the two coupled CMs, are equal in magnitude but produce counter propagating circulations of light resulting in high field intensities in the grooves but a net zero power flow in the grooves as equal amounts of power flow up and down each groove.

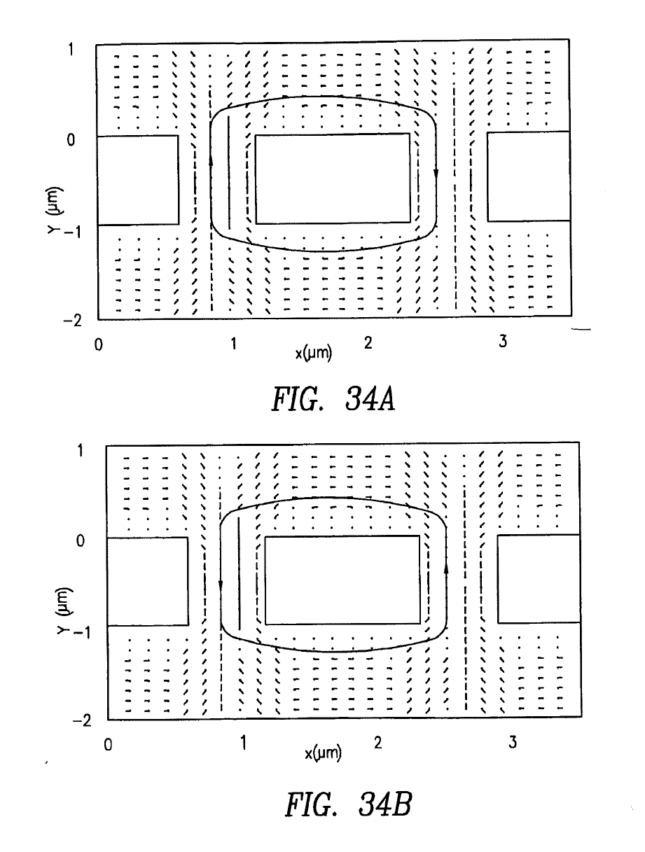

FIGS. 34A and B show the Poynting vector profiles for s-polarized light at energies slightly smaller and larger than the wavelength of the transmission minimum respectively. One of two things occurs on either side of the it resonance transmission minimum, depending on whether it is op-polarized or s-polarized it mode, however both things involve a competition between the two transmission channels produced by the two coupled CMs in neighboring grooves. Focusing on the s-polarization, on either side of the more symmetric s-polarized π resonance transmission minimum (more symmetric compared top-polarized π modes), one transmission channel associated with one set of grooves becomes weaker than the other transmission channel associated with the other set of grooves. Thus, of the two transmission channels that are presented to incident light, larger amounts of power are transmitted through the stronger transmission channel (i.e., one set of grooves) relative to the weaker transmission channel (i.e., the other set of grooves).

However, the weaker transmission channel is still strong enough to present to the now transmitted light on the substrate side, a strong and viable transmission channel back through the grating. This weaker transmission channel is the only channel possible because the transmitted light will not curve 180° and go back through the same groove through which it was initially transmitted. The net result of this process is a high reflectance. For energies progressively further from the transmission minimum, the weaker transmission channel re-transmits progressively lesser amounts of light which had been transmitted to the substrate via the stronger transmission channel, resulting in decreasing light circulation and increasing transmissivity.

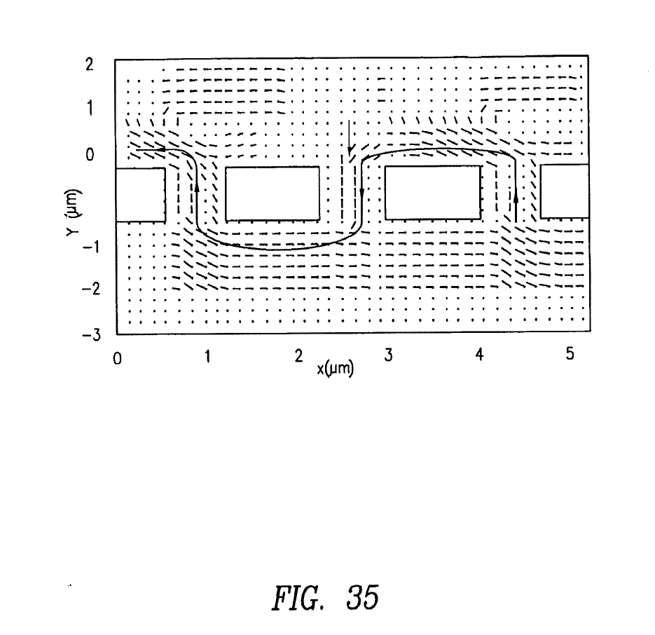

Referring to FIG. 35, for off-normal incident angle, this light circulation turns into light weaving for the particular grating parameters applied, as the light weaves its way back and forth through the structure while having a net power flow in one direction. Numerous other structures with more than two grooves per period are within the cope of this invention, including those with multiple layers of multiple-groove-per-period gratings, in which light weaves and circulates around the metal wires in increasingly complex ways.

Though specific examples of PETS gratings for enhanced TM, TE or simultaneous enhanced TM- and TE-transmission and also those optimized for light circulation and weaving are described herein, one of ordinary skill in the art will recognize that various known methods can be used to iteratively vary one or more parameters of the grating structure to optimize the design of any grating structure adapted to support CMs as described herein. As a result, it is understood that the scope of the present invention includes any sub-wavelength grating structure adapted to support CMs at a predetermined wavelength as described herein, including any grating structure formed in accordance with any embodiment of the method of the present invention for optimizing and tuning the grating structures, described herein including in the “Examples” section.

The present invention also includes sub-wavelength aperture array structures formed in thin films in such a way to produce high-efficiency polarization and wavelength dependent structures, transmitting and/or reflecting polarized light incident at one or more predetermined wavelengths. These multiple-apertures-per-unit-cell arrays can be structured according to the methods described herein to perform the following functions: polarizing, wavelength filtering, light channeling, localizing light, light weaving and circulation.

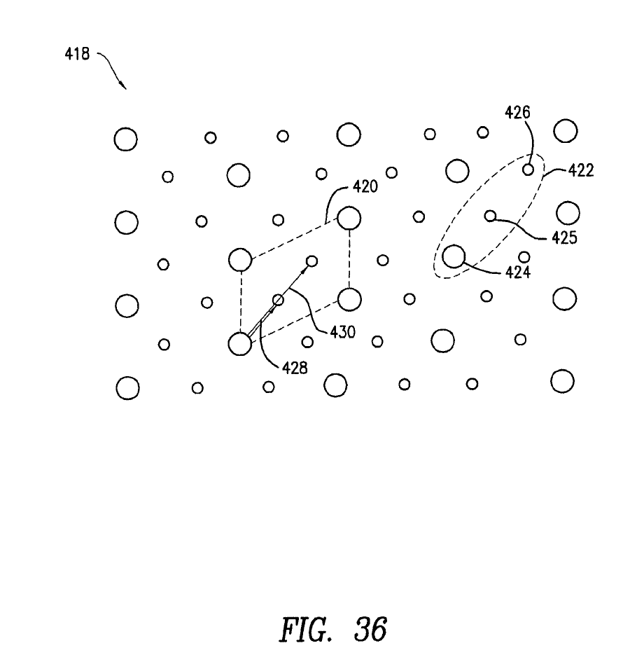

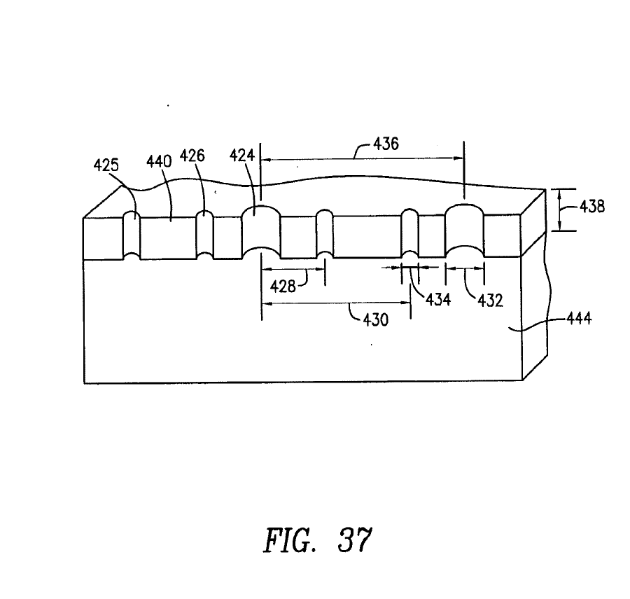

Referring to FIGS. 36 and 37, an embodiment of an aperture array structure 418 of the present invention includes a two-dimensional periodic array of a repeating unit cell 420 formed in a thickness 438 of thin film 440. The unit cell 420 includes a basis 422 of three apertures: one 424 having a larger diameter d1 432 than the other two apertures 425, 426, which have equivalent diameters d2 434. Displacement vectors v1 428 and v2 430 describe the orientation and spacing of each of the two apertures 425, 426 from the larger aperture 424, respectively. The unit cell 420 repeats with a periodicity Λ 436 as shown in FIG. 37. The aperture array structure 418 can also be characterized for convenience as including three sub-arrays of apertures. A first sub-array is formed from all identical apertures 424. Likewise, a second and third sub-array are formed from identical apertures 425 and 426, respectively. The apertures forming a sub-array are identical to one another, including in composition: the apertures forming a sub-array can be filled with the same dielectric material. The dielectric material filling the apertures can have a dielectric constant greater than or equal to 1 and preferably equal to or less than 40.

A high-efficiency polarizing beam-splitter of the present invention includes the aperture array structure 418 deposited on a substrate 444, which can include a single layer or multiple layers of any suitable substrate materials as described herein. The apertures of each unit cell 420 can be dimensioned and positioned and the periodicity of the array structure 418 chosen to form a beam-splitter that can operate at one or more predetermined wavelengths. The number of wavelengths that can be filtered depends on the number and relative orientations and dimensions of the apertures within one unit cell 420. In addition, different polarization states can be selected for transmission or reflection by adjusting the shapes of the apertures. This is a property of these sub-wavelength aperture array structures that is useful for a number of different applications.

Accordingly, the aperture array structure of the present invention can be configured as a wavelength filter and as any one or combination of: a transverse electric pass polarizer (either absorbing polarizer or beam-splitting polarizer); a transverse magnetic pass polarizer (either absorbing polarizer or beam-splitting polarize); an intensity detector; and a phase detector for individual or multiple wavelengths or ranges of wavelengths.

Similarly, a wavelength and/or polarization sensitive photodetector can include embodiments of the aperture array structure 418 of the present invention. The photodetector can be capable of single or multiple wavelength filtering and polarization selection. The construction of the unit cell and selection of the periodicity of the array structure will determine the wavelength(s) and polarization state(s) detected. Apertures of the same dimension, shape and dielectric composition within a unit cell can transmit a wavelength and/or polarization different than that transmitted through a differently shaped or composed aperture within the same unit cell.

The inventors have discovered the unexpected result that light-circulation can be produced and enhanced transmission maintained in such aperture array structures having more than one aperture per unit cell, if at least one aperture within a unit cell differs sufficiently from the others within the unit cell, but not enough to prevent phase interactions occurring between the CMs associated with each aperture.

Light circulation due to excited and coupled CMs has not been shown in the prior art for any periodic structure. The inventors have discovered that CMs in aperture arrays are produced by waveguide modes or VSPs within the apertures. In addition, they found that incident light at a predetermined angle of incidence, wavelength and polarization can be transmitted through one set of identical apertures (a first sub-array) by excited CMs and then re-transmitted through a properly configured second set (a second sub-array) of identical apertures that are appropriately shaped, positioned, composed, or otherwise configured differently than the first set of apertures to result in a high net reflectivity for light at a predetermined wavelength, polarization and angle of incidence according to the methods described herein. Some of the re-transmitted light can also be redirected through the first sub-array apertures. The same aperture array structures can also exhibit light weaving at a properly selected angle of incidence, which as described above, is useful inter cilia for photodetectors and for the propagation of signals or data.

Any one or more of the following parameters of the apertures of one sub-array can differ from those of another sub-array of the aperture array structure: dimension, dielectric constant of materials filling the apertures, height of the apertures (thickness of thin film), shape, and orientation. Any other parameter that can be varied to affect the coupling of excited CM modes according to the present invention is also considered to be within the scope of this invention.

The apertures forming any sub-array can be of any suitable shape, including circular, elliptical, square, bowtie or figure eight.

The dimensions of each aperture within one repeating unit cell of an aperture array structure of the present invention are preferably at least 0.25% of the period Λ of the aperture array structure. The cumulative dimensions of the apertures can be as high as 95%. Dimension refers to diameter of a circular aperture, length and width of a rectangle, major and minor axes of an ellipse and so on.

The height 438 of any aperture, or thickness of the thin film surrounding the aperture, can be 0.05%-1000% of the period Λ.

The magnitude of the displacement vectors, or the distance between two neighboring apertures in a unit cell can be in the range of 1% of the shortest wavelength for which enhanced optical transmission or light circulation is desired through 95% of the largest wavelength for which enhanced optical transmission is desired.

The period Λ of the aperture array structure is on the order of 1 mm-400 mm and on the order or less than the wavelength of the incident radiation, where the operating wavelength or wavelengths is in the range of 1 mm-400 mm.

One of ordinary skill in the art will recognize that the array dimensions can be scaled by an appropriate factor such that the wavelengths at which resonant cavity modes occur in the resulting aperture arrays are centered in any part of a predetermined operating wavelength regime: for example, the period Λ is on the order of 1 nm to 400 nm for operating in the deep ultra-violet and ultra-violet region of the electromagnetic spectrum of 1 nm-400 nm and so on.

The thin film of an aperture array structure of the present invention is preferably metallic, for example, any one or more of gold, silver, aluminum, copper, platinum, tungsten, titanium, hafnium, tantalum, lanthanum, lead, tin, iron or any alloy of these metals.

An aperture array structure of the present invention can be superposed on any suitable substrate including silicon (including polycrystalline or amorphous), germanium, silica, fused silica, silicon dioxide, quartz, gallium arsenide, indium phosphide, indium arsenide, gallium nitride, indium nitride, gallium indium nitride, gallium aluminum arsenide, indium antimonide, mercury cadmium telluride, mercury telluride, sapphire cadmium telluride, cadmium sulfide, cadmium selenide, glass, elastomer, polymer, crystalline powder, or any other suitable dielectric, oxide or semiconductor material.

The dielectric material filling the apertures in a sub-array can include any suitable material (or with nothing other than air) including: silica, silicon oxide, silicon dioxide, polycrystalline silicon, hafnium oxide, or any other suitable material including those listed herein as substrate and thin film materials and alloys thereof.

An aperture array structure of the present invention can also include a passivation or protective layer superposed thereon. The protective layer can include any suitable material including one or more of a polymer, plastic, oxide, or glass.

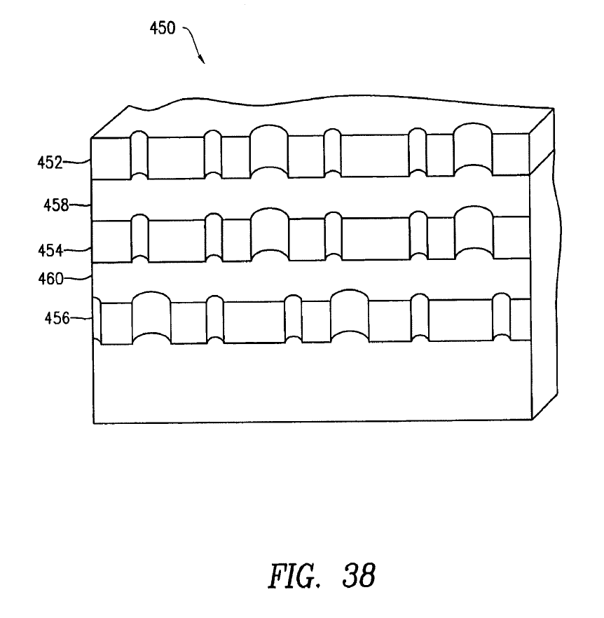

Referring to FIG. 38, a so-called aperture array “superstructure” 450 can be formed by layering any number of the same or different aperture array structures 452, 454, 456, for example, of the present invention. It can be appreciated that such superstructures can be configured with multiple layers of aperture array structures to achieve, for example, enhanced optical transmission and light circulation of separate polarization states and multiple wavelengths. Light of any polarization or a specific polarization, for several wavelengths or a specific wavelength, can experience enhanced transmission, light channeling, light circulation and light localization.

The layered structures 452, 454, 456 can be oriented in any way relative to each other. They can be separated by any combination of air, patterned or unpatterned spacer layers 458 and 460, which can include any dielectric material suitable to produce light circulation, light channeling, or enhanced transmission at predetermined wavelength(s), polarization state(s) and angle(s) of incidence. The dielectric material can include crystalline silicon, polycrystalline silicon, amorphous silicon, silicon oxide, silicon nitride, gallium arsenide, aluminum arsenide, gallium aluminum arsenide, indium phosphide, indium antimonide, indium phosphide antimonide, gallium nitride, indium nitride, gallium indium nitride, silica, borosilicate glass, mercury cadmium telluride, cadmium sulfide, cadmium telluride, or some other semiconductor, oxide, polymer or plastic material.

As discussed herein, the structures formed in accordance with the present invention can be adapted to preferentially channel incident light at one predetermined wavelength and/or polarization into one sub-array of apertures (or gratings), and to preferentially channel incident light at another predetermined wavelength into a second sub-array of apertures. It will be appreciated that this spatial separation and localized concentration of wavelength and/or polarization is particularly useful for applications such as focal plane arrays or any other application that would benefit from efficient separation of incident radiation by wavelength range.

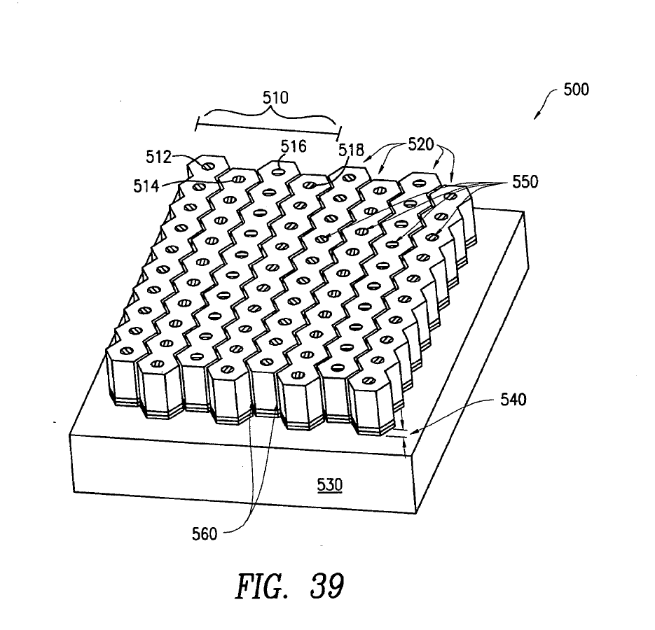

Referring to FIG. 39, a low-cost solar cell device 500 is formed in accordance with the present invention. The solar cell device 500 includes an array of apertures, or columnar cavities, in which individual solar cells are formed. The apertures are structured as repeating unit cells, each unit cell 510 having four different apertures. Therefore, four different sub-arrays of apertures are formed. The aperture array is structured according to the methods described herein to excite surface plasmons or optical cavity modes to preferentially channel incident unpolarized tight of a first wavelength band into a first aperture 512 (of a first sub-array), a second wavelength band into a second aperture 514 (second sub-array), a third wavelength hand into a third aperture 516 (third sub-array), and a fourth wavelength band into a fourth aperture 518 (fourth sub-array). Preferably, the different wavelength bands cover a total range of about 250 nm to 2500 nm.

In correspondence with the wavelength bands supported by each sub-array, the solar cells within the apertures of each sub-array are conventional single-junction solar cells composed of material that efficiently absorbs solar radiation within that same wavelength band.

The solar cells can be composed of any suitable material including silicon (both p-type, n-type and intrinsic), III-V semiconductors and their alloys (i.e., ternary and quaternary compound III-V semiconductors), II-VI semiconductors and their alloys (i.e., ternary and quaternary compound II-VI semiconductors) or other materials.

The solar cell device of the present invention comprise multiple different single-junction solar cells distributed horizontally over one single layer rather than vertically stacked like the tandem solar cells of the prior art. One significant advantage of this device is that it allows the use of electrochemical deposition techniques, such as chemical bath deposition, to fabricate the sets of semiconductor solar cells. These electrochemical techniques can be substantially cheaper than other fabrication techniques, such as molecular beam epitaxy and metal-organic chemical vapor deposition.

Referring again to FIG. 39, one unit cell 510 includes four different apertures, 512, 514, 516, and 518, referred to herein as columnar cavities, in which solar cells are positioned. These cavities are formed in a metallic film, and have a depth (thickness in film) of between 50 nanometers to 5 micrometers.

The columns of metal 520 surrounding the cavities are preferably separated from each other by open or filled spaces 560. These metallic columns can include any suitable conductive material, including aluminum, gold, silver, copper, titanium, tungsten, tin, or lead.

Each column can have a cross-sectional length of between 50 nanometers to 100 centimeters and a width of 50 nanometers to 10 micrometers.

The entire array of cavities containing solar cells can be superposed on a substrate 530. The substrate can be any material that is either rigid or flexible, e.g., glass, quartz, fused silica, silicon, plastic or other polymer material or any other material. The substrate can have thicknesses of 50 nanometers to 10 centimeters.

Each cavity can also be superposed on one or more layers 540 that serve afferent purposes (including adhesion promotion and electrical contact). For example, such layers may be added as adhesion promoters, electrical contacts, to eliminate deleterious reactions or intermixing of materials in the structure or other purposes. These layers can be of thicknesses between 0.1 nanometers to 1 centimeter and can be composed of platinum, titanium, tantalum, aluminum, chrome, silicon dioxide, polycrystalline silicon, silicon nitride, copper or any other conductive or insulating materials.

The columnar cavities 512, 514, 516, 518 defining the apertures can be of any suitable shape, including cylindrical, elliptical, rectangular, or square, which can be adapted for channeling and enhancing transmission within the particular wavelength range.

The cavities can have widths (i.e., diameters in the case of cylindrical cavities, or major and minor axes lengths in case of elliptical cavities, or widths and breadths in the case of rectangular or square cavities, or width in case of grooves) ranging from 50 nanometers to 5 micrometers. The dimensions of these cavities are chosen to produce surface plasmons on the walls of the cavity or an optical cavity mode within the cavity that acts as a tight whirlpool, sucking light (of a certain wavelength band) from distant areas into the cavity. These dimensions can vary depending on if surface plasmons or optical cavity modes are used to produce this effect, what material is in the cavity, and what material is at the base of the cavity, in accordance with the methods described herein. Both radii and depths for the cylindrical cavities, for example, can be in the range of 50 nanometers to 5 micrometers.

In another embodiment, a solar cell device of the present invention can be configured with a grating structure as described herein, wherein the grooves are filled with solar cells composed of the appropriate wavelength sensitive material.

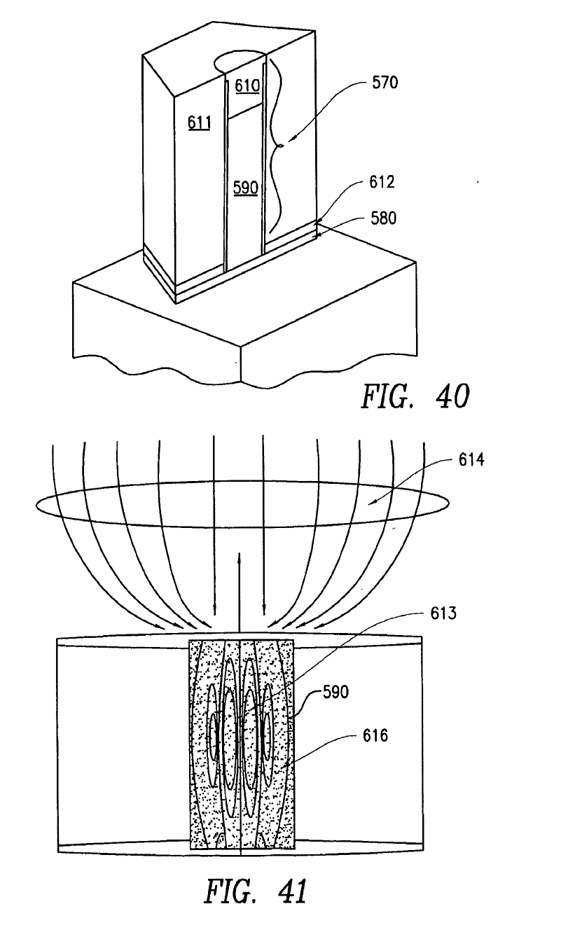

Referring to FIG. 40, a single absorbing cavity 570 of one of the solar cells is composed of a bottom electric contact 580, an absorbing semiconductor material 590, a window semiconductor material 610 and a second electrical contact 611.

Additional layers 612 of metal, insulator, polymer or other materials can be placed on the walls of the cavity in for various purposes. For example, layers of oxide, polymers, metals, insulators or other materials may be on the walls of the cavity, either entirely or partially, to serve different purposes including electrical insulation, chemical precursor for electrochemical deposition, provide a conductive layer to aid in the support of cavity modes or other purposes. This layer may have thickness of 0.1 nanometers to 5 micrometers.

The light channeling or whirlpool effect induced by the cavity and surface Plasmon mode coupling produces strong light concentration in the absorbing wells and can result in 30%-100% of the light of separate wavelength bands to be channeled into and absorbed within a small volume of solar cell material.

FIG. 41 is a Poynting vector representation of optical cavity modes 613 tuned to concentrate all of the light into the columnar cavity of FIG. 40. The arrows are the Poynting vectors 614. A contour map 616 also shows the electric field distribution within the cavity. Both show how the light is channeled and absorbed within the solar cell.

Although illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

What is claimed is:

1. A device for enhancing transmission of incident electromagnetic radiation at a predetermined wavelength comprising:
a structure comprising an array of apertures in a thin film, said structure adapted to preferentially support cavity modes for coupling to and enhancing transmission of a predetermined polarization state at said predetermined wavelength, said structure adapted to induce light circulation or weaving of said transmitted predetermined polarization state at said predetermined wavelength, wherein
said array of apertures are arranged with a periodicity that is equal to or less than said predetermined wavelength.

2. The device of claim 1, wherein said thin film comprises a metallic thin film.

3. The device of claim 1, wherein said thin film comprises one of aluminum, silver, gold, copper and tungsten.

4. The device of claim 1, wherein said structure is superposed on a substrate.

5. The device of claim 5, wherein said substrate comprises at least one of silica, silicon, silicon dioxide, Ge, GaAs, InP, InAs, AlAs, GaN, InN, GaInN, GaAlAs, InSb, fused silica, sapphire, quartz, glass, and BK7.

6. A light storage device comprising the device of claim 1.

7. The device of claim 1 wherein said apertures are filled with a dielectric material having a dielectric constant greater than 1.

8. A device for enhancing transmission of incident electromagnetic radiation at a predetermined wavelength, comprising:
a structure comprising an array of apertures in a thin film, said structure comprising a repeating unit cell having more than one aperture including a first aperture and a second aperture, wherein a parameter of said first aperture differs from that of said second aperture, and wherein said unit cell repeats with a periodicity on the order of or less than said predetermined wavelength; and wherein
said structure is adapted to preferentially support cavity modes for coupling to and enhancing transmission of a predetermined polarization state at said predetermined wavelength.

9. The device of claim 8, wherein said parameter of said first aperture that differs from that of said second aperture includes at least one of a dimension, height, dielectric constant of material filling said apertures, shape, and orientation.

10. The device of claim 8, wherein said first aperture of each said repeating unit cell is filled with a dielectric material having a dielectric constant greater than 1.

11. The device of claim 10, wherein said dielectric constant is less than 40.

12. The device of claim 10, wherein said first aperture of each said repeating unit cell is filled with one of silica, silicon oxide, silicon dioxide, polycrystalline silicon, and hafnium oxide.

13. The device of claim 8, wherein said structure is superposed on a substrate comprising at least one of silicon, amorphous silicon, polycrystalline silicon, germanium, silica, fused silica, silicon dioxide, quartz, gallium arsenide, indium phosphide, indium arsenide, gallium nitride, indium nitride, gallium indium nitride, gallium aluminum arsenide, indium antimonide, mercury cadmium telluride, mercury telluride, sapphire cadmium telluride, cadmium sulfide, cadmium selenide, glass, elastomer, polymer, crystalline powder, and any other suitable dielectric, oxide or semiconductor material.

14. The device of claim 8 adapted for use as a polarizing beamsplitter.

15. The device of claim 8 adapted for use as a polarizing beamsplitter for said predetermined wavelength and for a second predetermined wavelength, wherein said first aperture is dimensioned and positioned in said unit cell to preferentially transmit light at said predetermined wavelength and said second aperture is dimensioned and positioned in said unit cell to preferentially transmit light at said second predetermined wavelength.

16. A wavelength and polarization sensitive photodetector comprising the device of claim 12.

17. The device of claim 8, wherein said structure is further adapted to preferentially support cavity modes for inducing light circulation or weaving of said predetermined polarization state transmitted at said predetermined wavelength.

18. The device of claim 8, wherein a shape of at least one of said first and second aperture is one of circular, elliptical, square, bowtie and figure eight.

19. The device of claim 8, wherein a dimension of at least one of said first and second aperture is at least 0.25% of said periodicity of said array of apertures.

20. The device of claim 8, wherein a height of at least one of said first and second aperture is greater than or equal to 0.05% of said periodicity and less than 1000% of said periodicity.

21. The device of claim 8, wherein said thin film comprises at least one of gold, silver, aluminum, copper, platinum, tungsten, titanium, hafnium, tantalum, lanthanum, lead, tin, iron and any alloy of these metals.

22. The device of claim 8, further comprising a passivation layer superposed on said structure.

23. The device of claim 22, wherein said passivation layer comprises one or more of a polymer, plastic, oxide, and glass.

24. The device of claim 8, said device further adapted to enhance transmission of a range of wavelengths including said predetermined wavelength, said unit cell including a distance between said first and second apertures, wherein said distance is between 1% of a shortest wavelength of said range to 95% of a longest wavelength of said range.

25. A device for enhancing transmission of incident electromagnetic radiation at a first predetermined wavelength and a second predetermined wavelength, comprising:
a first structure comprising a first array of apertures in a first thin film, said first structure comprising a repeating unit cell having more than one aperture including a first aperture and a second aperture, wherein a parameter of said first aperture differs from that of said second aperture, and wherein said unit cell repeats with a first periodicity on the order of or less than said first predetermined wavelength; and wherein
said first structure is adapted to preferentially support cavity modes for coupling to and enhancing transmission of a first predetermined polarization state at said first predetermined wavelength;
a second structure comprising a second array of apertures in a second thin film, said second structure comprising a repeating unit cell having more than one aperture including a first aperture and a second aperture, wherein a parameter of said first aperture differs from that of said second aperture, and wherein said unit cell repeats with a second periodicity on the order of or less than said second predetermined wavelength; and wherein
said second structure is adapted to preferentially support cavity modes for coupling to and enhancing transmission of a second predetermined polarization state at said second predetermined wavelength; and
a spacer layer positioned between said first structure and said second structure.

26. The device of claim 25, wherein said spacer layer comprises at least one of a semiconductor, oxide, polymer or plastic material.

27. The device of claim 26, wherein said semiconductor material comprises at least one of crystalline silicon, polycrystalline silicon, amorphous silicon, silicon oxide, silicon nitride, gallium arsenide, aluminum arsenide, gallium aluminum arsenide, indium phosphide, indium antimonide, indium phosphide antimonide, gallium nitride, indium nitride, gallium indium nitride, silica, borosilicate glass, mercury cadmium telluride, cadmium sulfide, and cadmium telluride.

28. The device of claim 25, said first structure, second structure, and said spacer layer further adapted to induce light circulation, weaving, or channeling at said predetermined first and second wavelengths, first and second polarization states for at least one predetermined angle of incidence.

29. A device for enhancing transmission of incident electromagnetic radiation within at least a first and a second predetermined wavelength band and spatially separating said incident electromagnetic radiation according to said first and said second predetermined wavelength band, comprising:
a structure comprising an array of apertures in a thin film, said structure comprising a repeating unit cell having at least a first aperture and a second aperture, wherein a parameter of said first aperture differs from that of said second aperture, and wherein said unit cell repeats with a periodicity on the order of or less than at least said first and said second predetermined wavelength band; wherein
said structure is adapted to preferentially support cavity modes for coupling to and enhancing transmission of incident electromagnetic radiation within said first predetermined wavelength band and to channel said radiation within said first predetermined wavelength band preferentially into said first aperture; and wherein
said structure is adapted to preferentially support cavity modes for coupling to and enhancing transmission of incident electromagnetic radiation within said second predetermined wavelength band and to channel said radiation within said second predetermined wavelength band preferentially into said second aperture.

30. The device of claim 29 adapted for use as a solar cell device, wherein said thin film is an electrically conductive thin film, wherein said first aperture is filled with a first semiconductor material that efficiently absorbs said incident electromagnetic radiation within said first predetermined wavelength band, and wherein said second aperture is filled with a second semiconductor material that efficiently absorbs said incident electromagnetic radiation within said second predetermined wavelength band.
